(19) United States
(12) Patent Application Publication
(10) Pub. No.: US 2025/0321497 A1
(43) Pub. Date: Oct. 16, 2025

(54) ILLUMINATION OPTICAL SYSTEM, EXPOSURE APPARATUS, AND DEVICE MANUFACTURING METHOD

(71) Applicant: NIKON CORPORATION, Tokyo (JP)

(72) Inventors: Koichiro KOMATSU, Niiza-shi (JP); Satoshi KAWADO, Tokyo (JP); Tomoyuki OHKAWA, Fujisawa-shi (JP)

(73) Assignee: NIKON CORPORATION, Tokyo (JP)

(21) Appl. No.: 19/249,603

(22) Filed: Jun. 25, 2025

Related U.S. Application Data
(63) Continuation of application No. PCT/JP2023/044847, filed on Dec. 14, 2023.

(30) Foreign Application Priority Data
Dec. 27, 2022 (JP) 2022-210527

(51) Int. Cl. G03F 7/00

(52) U.S. Cl. CPC G03F 7/70208; G03F 7/7005; G03F 7/70075; G03F 7/7015; G03F 7/70358; G03F 7/7055

(57) ABSTRACT

There is provided an illumination optical system including: a light source; a fly-eye lens; and a condenser lens. The light source includes: a first light emitter configured to emit a first light flux; and a second light emitter configured to emit a second light flux. The light source is configured to selectively emit the first light flux or the second light flux. The second light emitter is configured such that a shape of a cross section of the second light flux at an incidence surface of the fly-eye lens is different from a shape of a cross section of the first light flux at the incidence surface, or that a dimension of the cross section of the second light flux at the incidence surface is different from a dimension of the cross section of the first light flux at the incidence surface.

### REFERENCE TO RELATED APPLICATIONS

This application is a Continuation Application of International Application No. PCT/JP2023/044847 claiming the conventional priority of Japanese Patent Application No. 2022-210527 filed on Dec. 27, 2022. The entire content of Japanese Patent Application No. 2022-210527 and the entire content of International Application No. PCT/JP2023/044847 are incorporated herein by reference.

### TECHNICAL FIELD

The present disclosure relates to an illumination optical system, an exposure apparatus, and a device manufacturing method.

### BACKGROUND

An exposure apparatus used for manufacturing various devices such as semiconductor devices includes an illumination optical system configured to irradiate a pattern formed on a mask with light and a projection optical system configured to form an image of the pattern on a substrate by imaging light transmitted through the pattern on the substrate. The illumination optical system is required to be capable of realizing various illumination conditions according to characteristics of a pattern, following diversification of patterns in recent years.

An aperture stop is disposed on an optical path of the illumination optical system (Japanese Patent Application Laid Open No. 2016-188878). As one type of the aperture stop, a variable diameter aperture stop capable of changing an illumination condition is known.

### SUMMARY

A change of an illumination condition using an aperture stop is performed by blocking a part of light from a light source with the aperture stop. Therefore, a part of energy of the light from the light source is absorbed by the aperture stop, resulting in loss of light intensity (power loss).

The present disclosure aims to provide an illumination optical system, an exposure apparatus, and a device manufacturing method capable of changing an illumination condition while reducing loss of light intensity.

In accordance with a first aspect of the present disclosure, there is provided, an illumination optical system configured to illuminate an irradiation objective surface, the illumination optical system including:
a light source;
a fly-eye lens arranged in an optical path between the light source and the irradiation objective surface; and
a condenser lens configured to overlap a plurality of light fluxes from the fly-eye lens with each other on the irradiation objective surface, wherein:
the light source includes:
   a first light emitter which has a first light emitting surface and a first optical element, and which is configured to emit a first light flux emitted from the first light emitting surface via the first optical element; and
   a second light emitter which has a second light emitting surface and a second optical element, and which is configured to emit a second light flux emitted from the second light emitting surface via the second optical element;
the light source is configured to selectively emit the first light flux from the first light emitter or the second light flux from the second light emitter; and
the second light emitter is configured such that a shape of a cross section of the second light flux at an incidence surface of the fly-eye lens is different from a shape of a cross section of the first light flux at the incidence surface of the fly-eye lens, or such that a dimension of the cross section of the second light flux at the incidence surface of the fly-eye lens is different from a dimension of the cross section of the first light flux at the incidence surface of the fly-eye lens.

In accordance with a second aspect of the present disclosure, there is provided an exposure apparatus including:
the illumination optical system of the first aspect configured to illuminate the irradiation objective surface; and
a projection optical system configured to irradiate a substrate with a light from the irradiation objective surface.

In accordance with the third aspect of the present disclosure, there is provided an exposure apparatus configured to perform a scanning exposure of a pattern on a mask onto a substrate, the exposure apparatus including:
a plurality of illumination optical systems configured to illuminate the pattern;
a plurality of projection optical system configured to form an image of the pattern on the substrate; and
a controller configured to control the scanning exposure, wherein:
the plurality of illumination optical system includes:
   a first illumination optical system configured to irradiate a first illumination area with illumination light; and
   a second illumination optical system configured to irradiate a second illumination area with illumination light, the second illumination optical system being the illumination optical system of the first aspect;
the first illumination area and the second illumination area overlap with each other in a non-scanning direction orthogonal to a scanning direction in which the exposure apparatus performs the scanning exposure; and
the controller is configured to change illuminance distribution of the second illumination optical system based on illuminance distribution of the first illumination optical system.

In accordance with the fourth aspect of the present disclosure, there is provided a device manufacturing method including:
exposing a pattern onto the substrate by using the exposure apparatus of the second or third aspect;
forming a mask layer on a surface of the substrate by developing the substrate to which the pattern has been exposed, the mask layer having a shape corresponding to the pattern; and
processing the surface of the substrate via the mask layer.

According to the illumination optical system, the exposure apparatus, and the device manufacturing method of the present disclosure, an illumination condition can be changed while reducing loss of light intensity.

### BRIEF DESCRIPTION OF DRAWINGS

FIG. 1 is a schematic diagram depicting configuration of exposure apparatuses of first and second embodiments of the present disclosure.

FIG. 2 is a schematic diagram depicting an internal configuration of the illumination optical system of the first embodiment of the present disclosure.

FIG. 3 is a schematic diagram depicting a configuration of a fiber group of a light source unit of the first embodiment.

FIG. 4 is a diagram depicting an arrangement of a plurality of light emitting surfaces in a light emitting area of the light source unit of the first embodiment.

FIG. 5A is a diagram depicting an optical path of the illumination optical system of the first embodiment of the present disclosure in a case where emitting ends of large diameter fibers solely emit light. FIG. 5B is a diagram depicting a situation in which the emitting ends of the large diameter fibers solely emit light in the light emitting area of the light source unit. FIG. 5C depicts an image formed in an incidence surface of a fly-eye lens by light from the large diameter fibers.

FIG. 6A is a diagram depicting an optical path of the illumination optical system of the first embodiment of the present disclosure in a case where emitting ends of medium diameter fibers solely emit light. FIG. 6B is a diagram depicting a situation in which the emitting ends of the middle diameter fibers solely emit light in the light emitting area of the light source unit. FIG. 6C depicts an image formed in the incidence surface of the fly-eye lens by light from the medium diameter fibers.

FIG. 7A is a diagram depicting an optical path of the illumination optical system of the first embodiment of the present disclosure in a case where emitting ends of small diameter fibers solely emit light. FIG. 7B is a diagram depicting a situation in which the emitting ends of the small diameter fibers solely emit light in the light emitting area of the light source unit. FIG. 7C depicts an image formed in the incidence surface of the fly-eye lens by light from the small diameter fibers.

FIG. 8A is a graph indicating illuminance distributions formed in an irradiation objective surface by light emitted from three large diameter fibers. FIG. 8B is a graph indicating an aspect in which inclined components of illuminance are corrected by adjusting an output power of semiconductor lasers.

FIG. 9 is a diagram depicting a positional relationship between an end face of an optical fiber and a collector lens in a light source unit of an illumination optical system of a modification of the first embodiment.

FIG. 10A is a diagram depicting an optical path in an illumination optical system of a second embodiment of the present disclosure in a case where emitting ends of normal illumination fibers solely emit light. FIG. 10B is a diagram depicting an image formed in the incidence surface of the fly-eye lens by light from the normal illumination fibers.

FIG. 11 is a schematic diagram depicting a configuration of a fiber group of a light source unit of the second embodiment.

FIG. 12 is a diagram depicting an arrangement of a plurality of light emitting surfaces in an light emitting area of the second embodiment.

FIG. 13A is a diagram depicting an optical path of the illumination optical system of the second embodiment of the present disclosure in a case where emitting ends of annular illumination fibers solely emit light. FIG. 13B depicts an image formed in the incidence surface of the fly-eye lens by light from the emitting ends of the annular illumination fibers.

FIG. 14A is a diagram depicting an optical path of the illumination optical system of the second embodiment of the present disclosure in a case where emitting ends of quadrupole illumination fibers solely emit light. FIG. 14B depicts an image formed in the incidence surface of the fly-eye lens by light from the emitting ends of the quadrupole illumination fibers.

FIG. 15 is a diagram depicting an arrangement of an emitting end of an optical fiber, an axicon lens, a collector lens, and two relay lenses in a light source unit of an illumination optical system of a modification.

FIG. 16 is a schematic diagram depicting an internal configuration of an illumination optical system of a modification. In this illumination optical system, an image of an emitting end of an optical fiber arranged in a light emitting area is formed at a position near an emitting plane of a fly-eye lens.

FIG. 17 is a flowchart depicting a manufacturing process of a semiconductor device.

FIG. 18 is a flowchart depicting a manufacturing process of a liquid crystal device such as a liquid crystal display element.

### DESCRIPTION OF EMBODIMENTS

### First Embodiment

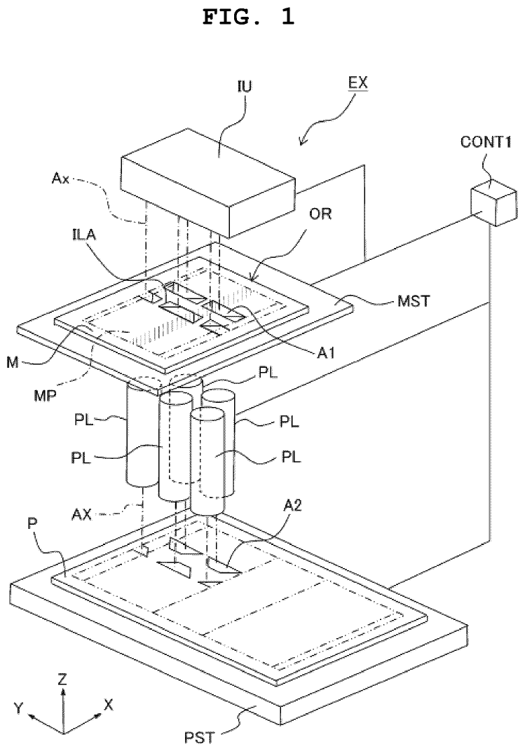

An illumination optical system IL1 and an exposure apparatus EX of the first embodiment will be described with reference to FIG. 1 to FIG. 9.

### Overall Configuration of Exposure Apparatus

The exposure apparatus EX is a projection exposure apparatus of a step-and-scan system (so-called scanner) that performs scanning exposure of an image of a pattern formed on a mask onto a substrate.

As depicted in FIG. 1, the exposure apparatus EX mainly includes an illumination unit IU, a mask stage MST, five projection optical systems PL arranged in a staggered pattern, a substrate stage PST, and a controller CONT1.

In the following description, the direction in which an optical axis AX of each of the five projection optical systems PL extends is defined as a Z direction (Z-axis direction). In the plane orthogonal to the Z direction, the direction (scanning direction) in which the mask M and the substrate P are moved synchronously during the scanning exposure is defined as a X direction (X-axis direction), and the direction (non-scanning direction) orthogonal to the X direction in the plane is defined as a Y direction (Y-axis direction). The X direction, the Y direction, and the Z direction are defined for convenience of description and can be changed in any manner. For example, in a case where the X direction, the Y direction, and the Z direction are defined in actual devices, the X direction in this description may be defined as a Y direction and the Y direction in this description may be defined as a X direction.

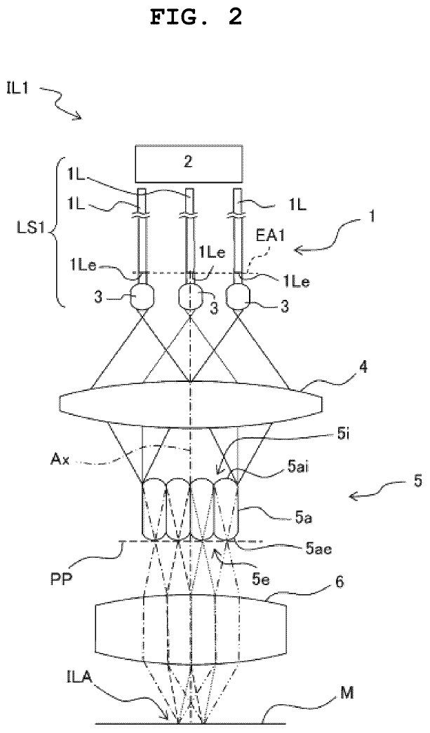

The illumination unit IU includes five illumination optical systems IL1 (FIG. 2) having the same internal configuration as each other. Each of the five illumination optical systems IL1 is configured to irradiate a rectangular illumination area ILA with illumination light (exposure light) for exposure. The five illumination optical systems IL1 are arranged in a staggered pattern, like the five projection optical system PL, in a state that an optical axis Ax of each of the five illumination optical systems IL1 coincides with the Z direction. The internal configuration of the illumination optical system IL1 will be described below.

The mask stage MST holds the mask M substantially parallelly to the X-Y plane such that the top surface of the mask M is located in the illumination area ILA of the illumination optical system IL1. The mask stage MST is driven by the mask stage driving system (not depicted) to move in the X direction, Y direction, and a rotation direction around the Z direction. The position of the mask stage MST is measured by a mask stage measurement system (not depicted).

Each of the projection optical systems PL forms an image, of the exposure light transmitted through the mask M in a trapezoidal field area A1, in a trapezoidal exposure area A2 on the substrate P. As a result, an image of the pattern of the mask M is formed (exposed) on the substrate P.

Each of the projection optical systems PL is specifically, for example, a double telecentric optical system that forms an erected and non-reversed image. Optical systems that can be used as the projection optical systems PL are described, for example, in Japanese Patent Application Laid-open No. H7-57986 and Japanese Patent Application Laid-open No. 2001-215718 by the applicant.

The substrate stage PST holds the substrate P substantially parallelly to the X-Y plane on the image plane-side of the projection optical system PL. The substrate stage PST is driven by a substrate stage driving system (not depicted) to move in the X direction, the Y direction, and a rotation direction around the Z direction. The position of the substrate stage PST is measured by the substrate stage measurement system (not depicted).

The control unit CONT1 controls the overall drive of the illumination unit IU, the mask stage MST, the projection optical system PL, and the substrate stage PST.

### Illumination Optical System IL1

The illumination optical system IL1 will be described.

As depicted in FIG. 2 to FIG. 5, the illumination optical system IL1 mainly includes a light source unit LS1, a relay lens 4, a fly-eye lens 5, and a condenser lens 6. The light source unit LS1 mainly includes an optical fiber (light guide) group 1, a semiconductor laser unit (source, or light source device) 2, a plurality of collector lenses 3, and a controller (illuminance distribution controller) CONT2.

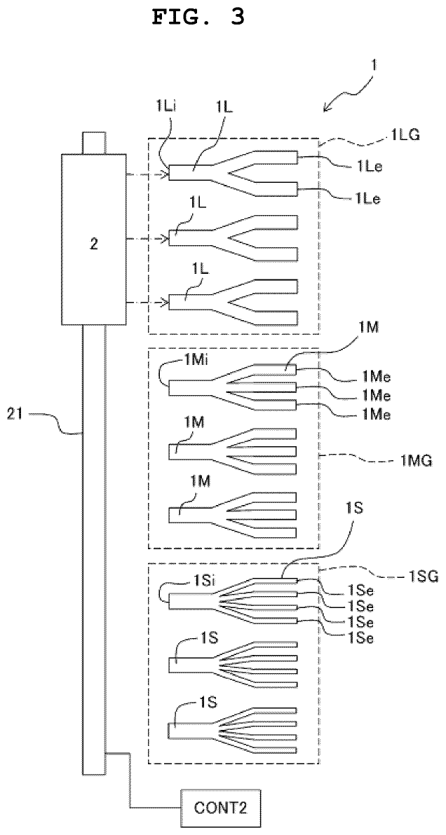

As depicted in FIG. 3, the optical fiber group 1 includes a large diameter fiber group 1LG including a plurality of large diameter fibers 1L, a medium diameter fiber group 1MG including a plurality of medium diameter fibers 1M, and a small diameter fiber group 1SG including a plurality of small diameter fibers 1S.

Each of the plurality of large diameter fibers 1L included in the large diameter fiber group 1LG has an incidence end 1Li into which light from the semiconductor laser unit 2 enters and an emitting end (light emitting surface) 1Le configured to emit the light entered into the large diameter fiber 1L. Each of the large diameter fibers 1L branches into two parts in the path from the incidence end 1Li to the emitting end 1Le, and thus has two emitting ends 1Le with respect to one incidence end 1Li. A core diameter of the large diameter fiber 1L may be 1.1 mm to 1.4 mm, and may be 1.06 mm to 1.33 mm, on the emitting end 1Le side.

Each of the plurality of medium diameter fibers 1M included in the medium diameter fiber group 1MG has an incidence end 1Mi into which light from the semiconductor laser unit 2 enters and an emitting end (light emitting surface) 1Me configured to emit the light entered into the medium diameter fiber 1M. Each of the medium diameter fibers 1M branches into three parts in the path from the incidence end 1Mi to the emitting end 1Me, and thus has three emitting ends 1Me with respect to one incidence end 1Mi. A core diameter of the middle diameter fiber 1M may be 0.5 mm to 0.9 mm, and may be 0.53 mm to 0.8 mm, on the emitting end 1Me side.

Each of the plurality of small diameter fibers 1S included in the small diameter fiber group 1SG has an incidence end 1Si into which light from the semiconductor laser unit 2 enters and an emitting end (light emitting surface) 1Se configured to emit the light entered into the small diameter fiber 1S. Each of the small diameter fibers 1S branches into four parts in the path from the incidence end 1Si to the emitting end 1Se, and thus has four emitting ends 1Se with respect to one incidence end 1Si. A core diameter of the small diameter fiber 1S may be 0.2 mm to 0.7 mm, and may be 0.26 mm to 0.53 mm, on the emitting end 1Se side.

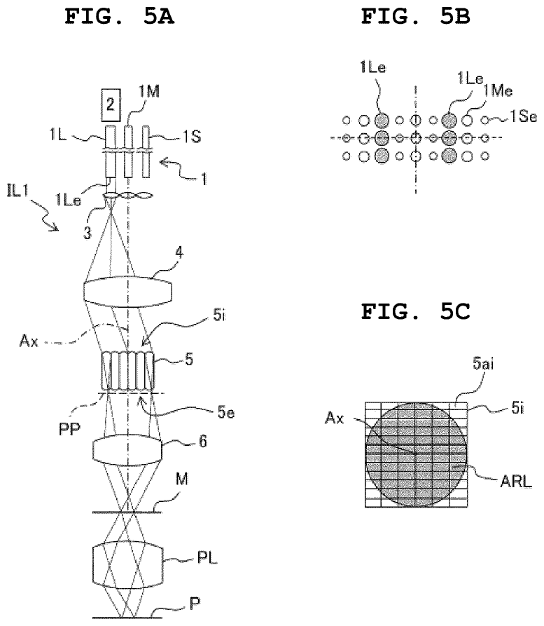

To avoid complication of the drawings, only three large diameter fibers 1L are depicted in FIG. 2, and only one large diameter fiber 1L, only one medium diameter fiber 1M, and only one small diameter fiber 1S are depicted in each of FIG. 5 to FIG. 7.

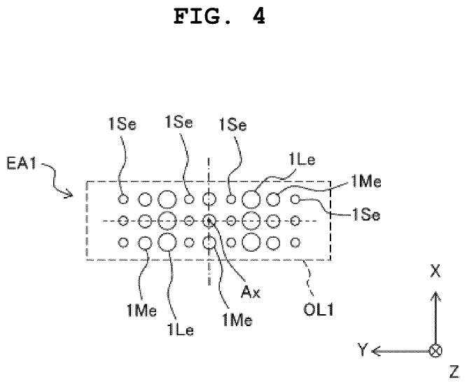

The emitting end 1Le of each of the large diameter fibers 1L, the emitting end 1Me of each of the medium diameter fibers 1M, and the emitting end 1Se of each of the small diameter fibers 1S are all circular flat surfaces. As depicted in FIG. 4, the emitting ends 1Le, 1Me, and 1Se are arranged in a plane orthogonal to the optical axis Ax of the illumination optical system IL1 such that the emitting ends 1Le, 1Me, and 1Se are flush with each other. Here, the planar area in which the emitting ends 1Le, 1Me, and 1Se are arranged flush with each other is referred to as an light emitting area EA1.

The arrangement of the emitting ends 1Le, 1Me, and 1Se in the light emitting area EA1 is as follows.

The emitting ends 1Le of the large diameter fibers IL are arranged in a matrix with three rows in the X direction and two columns in the Y direction. In the X direction, the emitting ends 1Le are arranged at equal intervals. In the X direction, the position of the center of the central emitting end 1Le in the X direction coincides with the position of the optical axis Ax. In the Y direction, the middle position of two emitting ends 1Le arranged side by side in the Y direction coincides with the position of the optical axis Ax. In such a manner, the emitting ends 1Le of the large diameter fibers 1L are arranged in point symmetry with the position of the optical axis Ax as a point of symmetry, in the light emitting area EA1.

The emitting ends 1Me of the middle diameter fiber 1M are arranged in a matrix with three rows in the X direction and three columns in the Y direction. In the X direction, the emitting ends 1Me are arranged at equal intervals. In the X direction, the position of the center of the central emitting end 1Me in the X direction coincides with the position of the optical axis Ax. In the Y direction, the emitting ends 1Me are arranged at equal intervals. In the Y direction, the position of the center of the central emitting end 1Me in the Y direction coincides with the position of the optical axis Ax. In such a manner, the emitting ends 1Me of the medium diameter fibers 1M are arranged in point symmetry with the position of the optical axis Ax as a point of symmetry, in the light emitting area EA1.

The emitting ends 1Se of the small diameter fibers 1S are arranged in a matrix with three rows in the X direction and four columns in the Y direction. In the Y direction, the distance between the emitting ends 1Se in the first row and the second row from one end in the Y direction and the distance between the emitting ends 1 Se in the third row and the fourth row from the one end in the Y direction are equal to each other, and each is greater than the distance between the emitting ends 1Se in the second row and the third row from the one end in the Y direction. In the X direction, the three emitting ends 1Se are arranged at equal intervals. In the X direction, the position of the center of the central emitting end 1Se in the X direction coincides with the position of the optical axis Ax. In the Y direction, the middle position of the emitting ends 1Se in the second row and the third row from the one end in the Y direction coincides with the position of the optical axis Ax. In such a manner, the emitting ends 1Se of the small diameter fibers 1S are arranged in point symmetry with the position of the optical axis Ax as a point of symmetry, in the light emitting area EA1.

By arranging each of the plurality of emitting ends 1Le, the plurality of emitting ends 1Me, and the plurality of emitting ends 1Se in point symmetry with the position of the optical axis Ax as a point of symmetry, the uniformity of the illuminance distribution in the illumination area ILA of the illumination optical system IL1 is improved (details will be described below).

In this embodiment, the plurality of emitting ends 1Le is arranged in point symmetry with respect to the optical axis Ax, and at the same time, the plurality of emitting ends 1Le is arranged in line symmetry with respect to a reference line extending in the X direction through the optical axis Ax and arranged in line symmetry with respect to a reference line extending in the Y direction through the optical axis Ax. The same is true for each of the plurality of emitting ends 1Me and the plurality of emitting ends 1Se. In a manner such as above, the plurality of emitting ends of the same type may be arranged in line symmetry with respect to a reference line extending in the X direction through the optical axis Ax and/or a reference line extending in the Y direction through the optical axis Ax, rather than in point symmetry with respect to the optical axis Ax.

In the embodiment, the X direction is the scanning direction of the exposure apparatus EX. Thus, the uniformity of the illuminance distribution in the direction (Y direction) orthogonal to the scanning direction can be improved by arranging the plurality of emitting ends of the same type (e.g., the plurality of emitting ends 1Le) in line symmetry with respect to a reference line extending in the scanning direction (X direction) through the optical axis Ax. In contrast, even if the plurality of emitting ends of the same type is not arranged in line symmetry with respect to a reference line extending in the Y direction through the optical axis Ax, the illuminance distribution in the X direction will be made uniform by the scanning exposure.

The semiconductor laser unit 2 includes three semiconductor lasers (laser diodes), and is configured to emit light fluxes respectively from the semiconductor lasers at different positions and in parallel with each other.

The semiconductor laser unit 2 is moved by the moving mechanism 21, and enters the light fluxes from the three semiconductor lasers into the three incidence ends 1Li of the large diameter fiber group 1LG, the three incidence ends 1Mi of the medium diameter fiber group 1MG, or the three incidence ends 1Si of the small diameter fiber group 1SG.

The light entered into each of the incidence ends 1Li repeats internal reflection in the large diameter fiber 1L, and then will be emitted from each of the emitting ends 1Le with a light intensity distribution being substantially uniform. The same is true for the light entered into each of the incidence ends 1Mi and the light entered into each of the incidence ends 1Si.

Although the arrangement of the large diameter fibers 1L, the medium diameter fibers 1M, and the small diameter fibers 1S is not limited to any specific aspect, each of the fibers may be held (arranged) in a straight line at a position near the emitting end 1Le, 1Me, or 1Se. Owing to such an arrangement, illuminance will be uniform at each of the emitting ends 1Le, 1Me, and 1Se. In a case where the optical fiber is arranged in a bent manner for the convenience of the apparatus configuration, the fiber may be bent in the X direction (i.e., the scanning direction).

The controller CONT2 performs moving of the semiconductor laser unit 2 by using the moving mechanism 21 and/or adjusting of the output power of the semiconductor laser unit 2 etc., based on, for example, the instructions of the controller CONT1 of the exposure apparatus EX.

A plurality of collector lenses (first optical element and second optical element) 3 is identical to each other. One collector lens 3 is arranged for each of the six emitting ends 1Le, each of the nine emitting ends 1Me and each of the twelve emitting ends 1Se. That is twenty seven collector lenses 3 in total are arranged. Each of the collector lenses 3 is arranged such that the optical axis of the collector lens coincides or substantially coincides with the center of the core of the corresponding emitting end 1Le, 1Me, or 1Se, and the optical axis of the collector lens is parallel to or substantially parallel to the optical axis Ax of the illumination optical system IL1. Each of the collector lenses 3 is arranged such that the position of the front focal point of the collector lens 3 coincides or substantially coincides with the position of the light emitting area EA1 (i.e., the plane in which the emitting ends 1Le, 1Me, and 1Se are arranged in flush with each other) in the direction of the optical axis Ax.

In such a manner, each of the collector lenses 3 is arranged such that the light flux from the corresponding emitting end solely enters into the collector lens 3. One collector lens 3 and the emitting end corresponding thereto form one light emitting part (light emitter). Each of the collector lenses 3 has a positive power.

The relay lens 4 is arranged such that the front focal point of the relay lens 4 is located in or near a plane in which the rear focal point of each of the collector lenses 3 is located. The relay lens 4 is arranged so that the optical axis of the relay lens 4 is parallel or substantially parallel to the optical axis Ax of the illumination optical system IL1.

The fly-eye lens 5 is an optical integrator having a plurality of lens elements (wavefront dividing elements) 5a arranged in parallel. The fly-eye lens 5 is arranged such that an incidence surface 5i is located near the rear focal point of the relay lens 4. The optical axes of the plurality of lens elements 5a are parallel to each other, and each is arranged to be substantially parallel to the optical axis Ax of the illumination optical system IL1.

The shape of the cross section of each of the lens elements 5a by a plane orthogonal to the optical axis of each of the lens elements 5a is a rectangle that is short in the X direction and long in the Y direction (FIG. 5C). Regarding each of the lens elements 5a, the focal position by the incidence surface 5ai (FIG. 2) coincides or substantially coincides with an emitting surface 5ae of the lens element 5a, and the focal position by the emitting surface 5ae coincides or substantially coincides with the incidence surface 5ai.

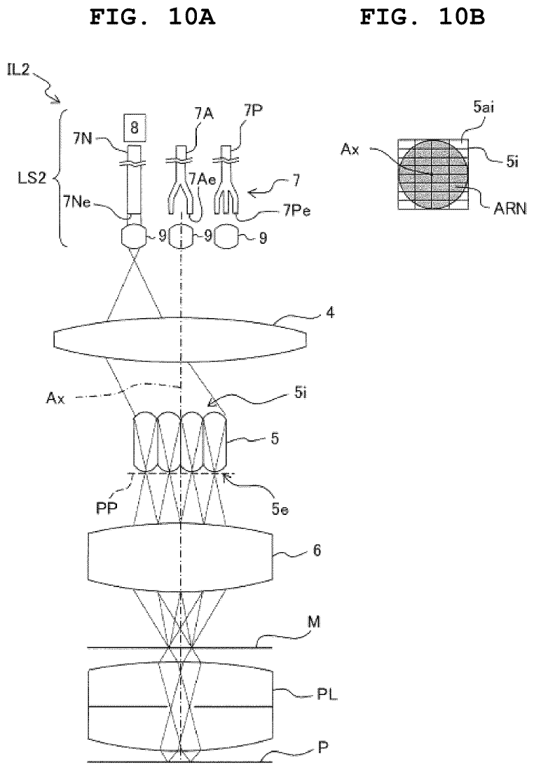

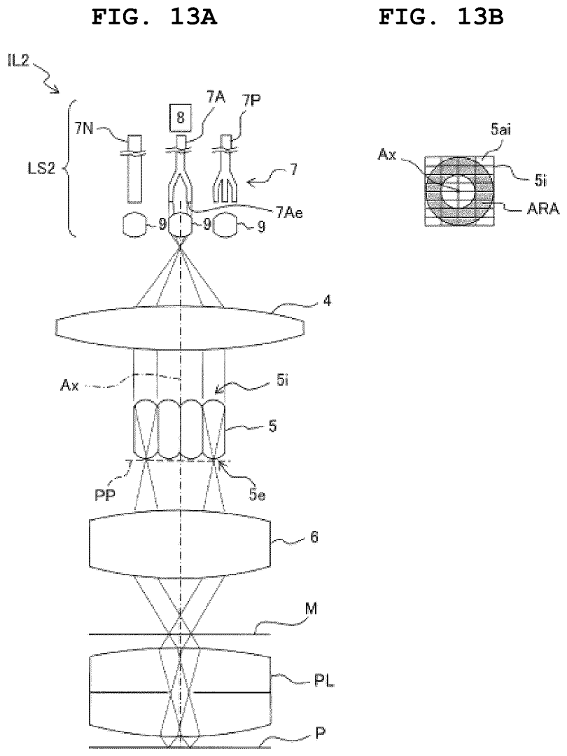

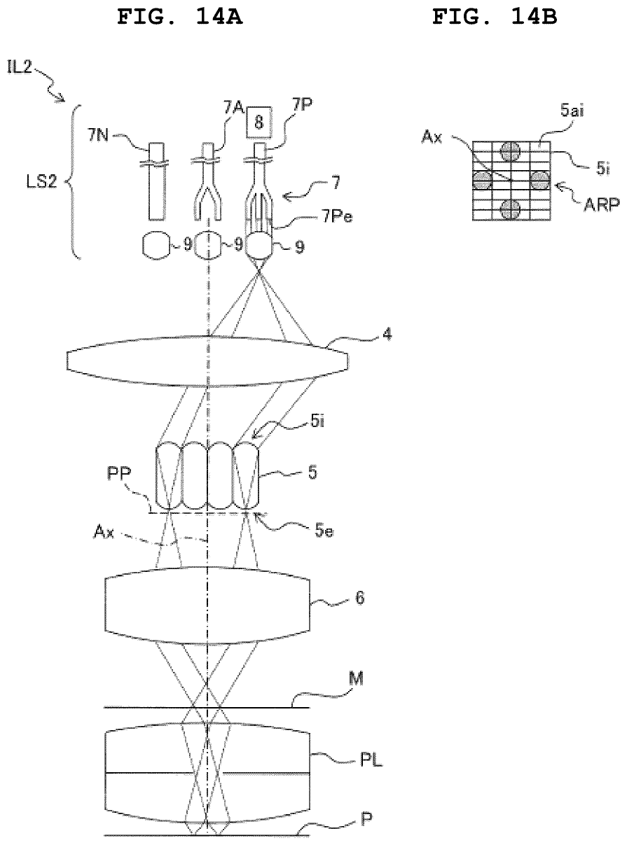

The fly-eye lens 5 includes a number of lens elements 5a arranged densely, for example, thirty to forty lens elements 5a in the X direction and eight to twelve lens elements 5a in the Y direction. The outer shape of the fly-eye lens 5 as a whole is substantially square. In each of FIG. 2, FIG. 5 to FIG. 7, FIG. 10, FIG. 13, FIG. 14, and FIG, 16, the number of lens elements 5a is reduced to avoid complication of the drawings.

The condenser lens 6 is arranged such that the position of the front focal point of the condenser lens 6 coincides or substantially coincides with the position of the emitting surface 5e of the fly-eye lens 5 in the direction of the optical axis Ax of the illumination optical system IL1. The condenser lens 6 is arranged such that the position of the rear focal point of the condenser lens 6 coincides or substantially coincides with the irradiation objective surface (the surface on which the mask M is to be arranged) in the direction of the optical axis Ax of the illumination optical system IL1. The condenser lens 6 is arranged such that the optical axis of the condenser lens 6 is parallel or substantially parallel to the optical axis Ax of the illumination optical system IL1.

The optical path of the illumination optical system IL1 having the above configuration will be described. Here, the optical path in a case where the emitting end 1Le of the large diameter fiber 1L emits light in the light source unit LS1 is described as an example. The optical path in a case where the emitting end 1Me of the medium diameter fiber 1M emits light and the optical path in a case where the emitting end 1Se of the small diameter fiber 1S emits light are similar to the light path described below.

The light emitted from each of the plurality of emitting ends 1Le substantially parallelly to the optical axis of the corresponding collector lens 3 (and consequently, substantially parallelly to the optical axis Ax of the illumination optical system IL1) is gathered at a position near the rear focal position of the collector lens 3. Then, the light from the collector lenses 3 enters the identical area in the incidence surface 5i of the fly-eye lens 5 overlapping with each other, by the effect of the relay lens 4 (FIG. 2). The light emitted from each point on the surface of each of the plurality of emitting end 1Le gathers on the incidence surface 5i of the fly-eye lens 5 via the collector lens 3 and the relay lens 4. Thus, a plurality of circle images of the plurality of emitting ends 1Le is projected onto the incidence surface 5i of the fly-eye lens 5 overlapped with each other, after having been magnified by the collector lens 3 and the relay lens 4.

The light from the plurality of emitting ends 1Le overlapped with each other on the incidence surface 5i of the fly-eye lens 5 is then divided two-dimensionally (wavefront division) by a number of lens elements 5a of the fly-eye lens 5. The light fluxes obtained by the wavefront division are emitted from the emitting surfaces 5ae of the lens elements 5a, and illuminate the illumination area ILA on the irradiation objective surface (the surface on which the mask M is to be arranged) overlappingly with each other via the condenser lens 6. Since the lens element 5a of the fly-eye lens 5 is rectangular being short in the X direction and long in the Y direction, the illumination area ILA is rectangular being short in the X direction and long in the Y direction, like the lens element 5a.

In the illumination optical system IL1, a plane that is the Fourier transform plane of the irradiation objective surface (the surface on which the mask M is to be arranged) can be defined at a position near the emitting surface 5e of the fly-eye lens 5. This plane is defined as an illumination pupil PP of the illumination optical system IL1. The illumination pupil PP is optically conjugate to the plane on which an aperture stop (not depicted) for determining an numerical aperture of the projection optical system PL is arranged. In the illumination optical system IL1, the irradiation objective surface (the surface on which the mask M is to be arranged) and the incidence surface 5ai of the lens element 5a of the fly-eye lens 5 are substantially conjugate to each other. In other words, the incidence surface 5ai of the lens element 5a of the fly-eye lens 5 will be magnified and projected onto the irradiation objective surface with magnification determined based on the focal length of the fly-eye lens 5 and the focal length of the condenser lens 6.

### Scanning Exposure by Exposure Apparatus EX

In a case where the scanning exposure of the image of the pattern MP formed on the mask M onto the substrate P is performed by using the exposure apparatus EX of the first embodiment, the mask M with the pattern MP formed thereon is placed on the mask stage MST of the exposure apparatus EX first, and then the substrate P coated with photosensitive resist is placed on the substrate stage PST (FIG. 1).

Next, the illumination optical system IL1 of the illumination unit IU irradiates the five illumination areas ILA on the mask M with the illumination light. The light, of the illumination light, transmitted through the mask M in each of the field areas A1 of the projection optical system PL forms image in the corresponding exposure area A2 on the substrate P via the projection optical system PL. As a result, an image of the pattern MP located in the field area A1 is formed on the substrate P located in the exposure area A2. In other words, a portion of the pattern MP is transferred to the resist layer of the substrate P. The trapezoidal shapes of the field area A1 and the exposure area A2 is defined by the shape of an aperture stop (not depicted) of the projection optical system PL.

By moving the mask stage MST to one side in the X direction (scanning direction) and moving the substrate stage PST to the other side in the X direction in synchronized manner while performing the irradiation of the illumination light by the illumination unit IU, a banded area of the pattern MP extending in the X direction is transferred to the banded area of the resist layer of the substrate P extending in the X direction (scanning exposure). After the transferring of the entire area of one banded area is completed, the mask stage MST is step-moved to one side in the Y direction (non-scanning direction) and the substrate stage PST is similarly step-moved to the other side in the Y direction. Then, the mask stage MST and substrate stage PST are moved synchronously in the scanning direction to perform the next scanning exposure.

In the area (hereinafter, referred to as “overlap area OR”) where two field areas A1 adjacent to each other in the Y direction overlap with each other in the Y direction, the mask pattern MP is transferred to the substrate P in two steps. That is, the mask pattern MP is transferred when the mask pattern MP is located in the end part (that is, a part in which the width in the X direction decreases as the position shifts to the positive side in the Y direction) of one field area A1 and when the mask pattern MP is located in the end part (that is, a part in which the width in the X direction increases as the position shifts to the positive side in the Y direction) of the other field area A1 adjacent to the one field area A1. In order to avoid complication of the drawing, in FIG. 1, only one of the plurality of overlap areas OR is explicitly indicated with hatching.

The total amount of exposure to the resist on the substrate P in the exposure of the overlap area OR is the same as the exposure amount in the other parts of the pattern MP. This is because the total amount of light transmitting through the mask M at the end parts of the field areas A1 through two projection lenses is identical to the amount of light transmitting through the mask M at the center of the field area A1 through one projection lens, owing to the arrangement of the two field areas A1 in which the edges of the trapezoidal shapes of the field areas A1 overlap with each other. In such a manner, by making the shape of the field area A1 trapezoid, and by performing the transferring in the overlap area OR via two field areas A1 adjacent to each other in the non-scanning direction, the pattern MP can be seamlessly transferred over the entire area in the Y direction. In the overlap area OR, two illumination areas ILA of two illumination optical systems IL1 configured to irradiate two field areas Al with the illumination light overlap with each other in the Y direction.

### Change of Illumination Condition

Next, change of the illumination condition in the illumination optical system IL1 of the first embodiment, specifically change of the coherence factor (σ value) and change of the illuminance uniformity, will be described.

(1) Change of Coherence Factor (σ value)

In a case where the pattern MP on the mask M is exposed onto the substrate P by using the exposure system EX, the coherence factor (σ value) may be changed according to a shape of the pattern MP. In general, increasing the σ value for patterns with dense fine lines, and decreasing the σ0 value for isolated patterns such as contact holes is preferable.

The σ value is defined as “σ value=aperture stop diameter/pupil diameter of projection optical system”, or “σ value=numerical apertures on emitting side of illumination optical system/numerical apertures on incidence side of projection optical system”. Therefore, the σ value can be decreased by disposing an aperture stop with a small diameter at a position of an illumination pupil of an illumination optical system to decrease a numerical apertures on an emitting side of the illumination optical system. In contrast, in a case where an aperture stop with a large diameter is disposed at the position of the illumination pupil, the numerical apertures on the emitting side of the illumination optical system increases, and the σ value also increases.

First, the case where the illumination condition is set to a σ value=“large” (as an example, σ=approximately 0.8 to 1.0) will be described with reference to FIG. 5A to FIG. 5C.

In this case, the controller CONT2 moves the semiconductor laser unit 2 such that light fluxes from the semiconductor laser unit 2 enter into the large diameter fiber group 1LG and are emitted from the emitting ends 1Le of the large diameter fibers 1L in the light emitting area EA1 (FIG. 5B). The light fluxes emitted from the six emitting ends 1Le enter into the identical area on the incidence surface 5i of the fly-eye lens 5 overlapping with each other, via the collector lenses 3 corresponding respectively thereto and the relay lens 4.

The area ARL on the incidence surface 5i (an aggregate of the rectangular incidence surfaces 5ai of the lens elements 5a) of the fly-eye lens 5 into which the light fluxes emitted from the six emitting ends 1Le enter overlapping with each other is a circular area substantially inscribed in the substantially square outline of the incidence surface 5i (FIG. 5C).

Here, as described above, the optical axes of the plurality of lens elements 5a of the fly-eye lens 5 are parallel to each other. Therefore, the light intensity distribution of the light flux entered into the incidence surface 5i of the fly-eye lens 5 is reflected in the light intensity distribution on the emitting surface 5e of the fly-eye lens 5, that is, the light intensity distribution at a position near the illumination pupil PP.

In such a manner, in a case where the light from each of the six emitting ends 1Le illuminates a wide area of the incidence surface 5i of the fly-eye lens 5, the light intensity distribution at the illumination pupil PP has a state in which the distribution spreads to a position farther from the optical axis Ax, that is a state similar to a state realized in a case where the aperture stop with large diameter is disposed at the illumination pupil PP. Therefore, the numerical aperture on the emitting side of the illumination optical system IL1 is large, and the σ value is large as well.

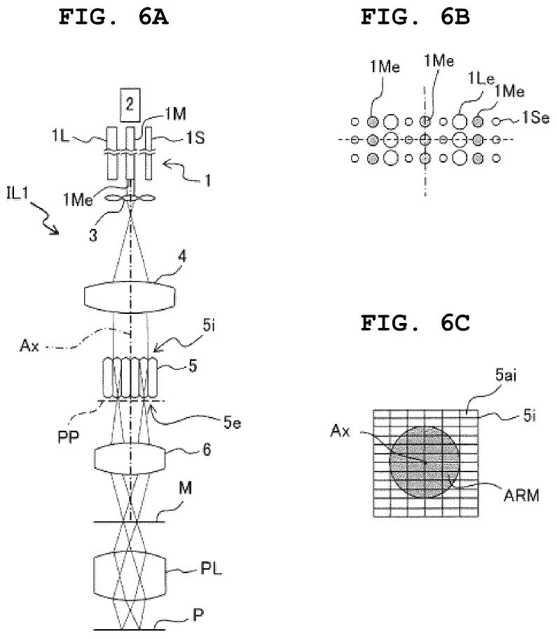

Next, the case where the illumination condition is set to σ value=“medium” (as an example, σ=approximately 0.4 to 0.6) will be described with reference to FIG. 6A to FIG. 6C.

In this case, the controller CONT2 moves the semiconductor laser unit 2 such that the light fluxes from the semiconductor laser unit 2 enter the medium diameter fiber group 1MG, and are emitted from the emitting ends 1Me of the medium diameter fibers 1M in the light emitting area EA1 (FIG. 6B). The light fluxes emitted from the nine emitting ends 1Me enter into the identical area of the incidence surface 5i of the fly-eye lens 5 overlapping with each other, via the collector lenses 3 corresponding respectively thereto and the relay lens 4.

The emitting end 1Me of the medium diameter fiber 1M has a diameter smaller than the diameter of the emitting end 1Le of the large diameter fiber 1L. Therefore, in the incidence surface 5i of the fly-eye lens 5, the area ARM into which the light fluxes each emitted from one of the nine emitting ends 1Me enter overlappingly is a circular area having a diameter smaller than the diameter of the area ARL formed in the case of the large diameter fiber 1L (FIG. 6C).

Therefore, the light intensity distribution in the illumination pupil PP is a circular distribution with a diameter smaller than a diameter realized in a case where the light is emitted from the large diameter fiber 1L. That is, the light intensity distribution in the illumination pupil PP has a state same as a state realized when the aperture stop with middle diameter is disposed at the illumination pupil PP. As a result, the numerical apertures on the emitting side of the illumination optical system IL1 is medium, and the o value is medium as well.

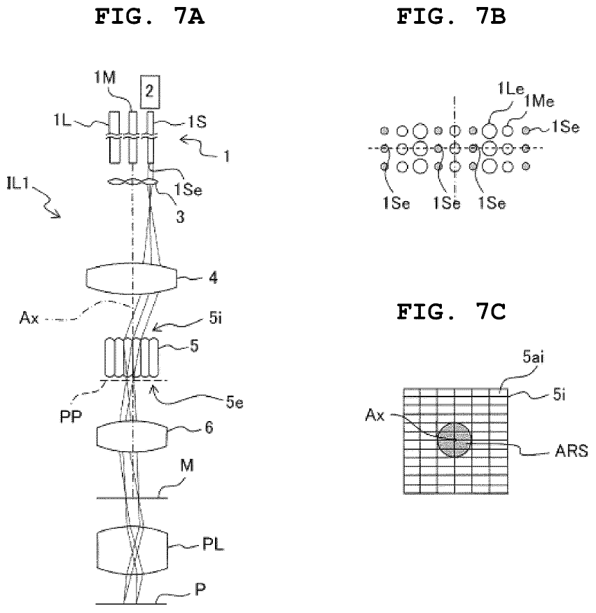

Next, the case where the illumination condition is set to a σ value=“small” (as an example, σ=approximately 0.2 to 0.4) will be described with reference to FIG. 7A to FIG. 7C.

In this case, the control unit CONT2 moves the semiconductor laser unit 2 such that the light fluxes from the semiconductor laser unit 2 enter into the small diameter fiber group 1SG and are emitted from the emitting ends 1Se of the small diameter fibers 1S in the light emitting area EA1 (FIG. 7B). The light fluxes emitted from the twelve emitting ends 1Se enter into the identical area of the incidence surface 5i of the fly-eye lens 5 overlapping with each other, via the collector lenses 3 corresponding respectively thereto and the relay lens 4 (FIG. 7A).

The emitting end 1Se of the small diameter fiber 1S has a diameter smaller than the diameter of the emitting end 1Me of the medium diameter fiber 1M. Therefore, in the incidence surface 5i of the fly-eye lens 5, an area ARS into which the light fluxes each emitted from one of the twelve emitting ends 1Se enter overlappingly is a circular area having a diameter smaller than the diameter of the area ARM formed in the case of the medium diameter fiber 1M (FIG. 7C).

Therefore, the light intensity distribution in the illumination pupil PP is a circular distribution with a diameter smaller than the diameter realized in a case where the light is emitted from the medium diameter fiber 1M. That is, the light intensity distribution in the illumination pupil PP has a state same as a state realized when the aperture stop with small diameter is disposed at the illumination pupil PP. As a result, the numerical aperture on the emitting side of the illumination optical system IL1 is small, and the o value is small as well.

As described above, in the illumination optical system IL1 of the embodiment, the o value can be changed by switching the emitting end that emits light in the light emitting area EA1 and consequently changing the dimension of the cross section of the light flux at the incidence surface 5i of the fly-eye lens 5.

### (2) Change of Illuminance Distribution

The illuminance of the illumination light that enters into the illumination area ILA from the illumination optical system IL may be uniform, and as an example, the range of illuminance unevenness may be 1% or less.

In this respect, in the light emitting area EA1 of the light source unit LS1 of the illumination optical system IL of the first embodiment, the set of the plurality of emitting ends 1L of the large diameter fibers 1L, the set of the plurality of emitting ends 1Me of the medium diameter fibers 1M, and the set of the plurality of emitting ends 1Se of the small diameter fibers 1S are each arranged in point symmetry with the optical axis Ax as a point of symmetry. Therefore, the illuminance distribution in the illumination area ILA has a high uniformity.

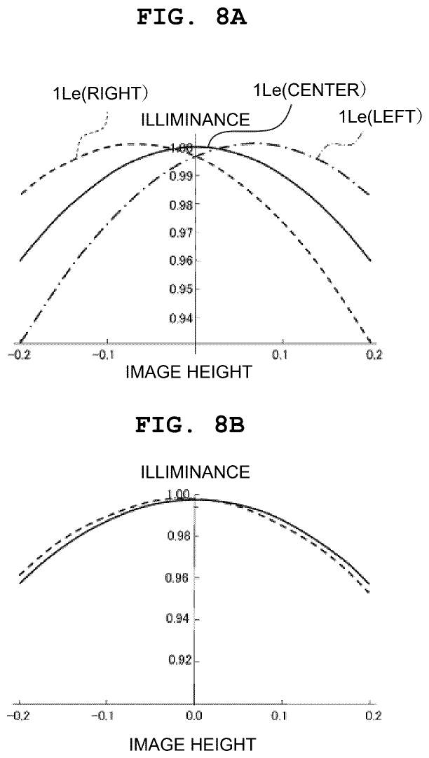

The reason will be described with reference to FIG. 2 and FIG. 8A. The solid line in FIG. 8A indicates the illuminance distribution in the illumination area ILA by the light flux emitted from the emitting end 1Le depicted at the center in FIG. 2 and transmitted through one lens element 5a of the fly-eye lens 5. The dotted line in FIG. 8A indicates the illuminance distribution in the illumination area ILA by the light flux emitted from the emitting end 1Le depicted at the right in FIG. 2 and transmitted through one lens element 5a of the fly-eye lens 5. The alternate long and short dash line in FIG. 8A indicates the illuminance distribution in the illumination area ILA by the light flux emitted from the emitting end 1Le depicted at the left in FIG. 2 and transmitted through one lens element 5a of the fly-eye lens 5. The horizontal axis in FIG. 8A represents the image height. Here, the image height is the position in the X direction or the position in the Y direction within the illumination area ILA. The vertical axis of FIG. 8A represents illuminance.

According to the findings of the inventor of the application, the reason why the graph indicating the illuminance distribution by each light flux has an arch shape is the influence of spherical aberration at the incidence surface 5ai of the lens element 5a of the fly-eye lens 5. Further, the reason why the illuminance distribution by the light flux emitted from the right or left emitting end 1Le in FIG. 2 is shifted to the left or right compared to the illuminance distribution by the light flux emitted from the central emitting end 1Le in FIG. 2, is the fact that the light flux emitted from each emitting end 1Le in FIG. 2 enters the fly-eye lens 5 at an angle to the optical axis Ax. The amount of shift of the illuminance distribution in the illumination area ILA depends on the magnitude of the incidence angle of the light flux forming the illuminance distribution to the fly-eye lens 5.

In view of the above, if two light fluxes are caused to enter into the fly-eye lens 5 symmetrically with respect to the optical axis Ax, the illuminance distributions formed in the illumination area ILA by the two light fluxes will shift with respect to the optical axis Ax in directions opposite from each other and by the same amount. In addition, since the light fluxes to enter into the fly-eye lens 5 symmetrically with respect to the optical axis Ax maintain the relationship of symmetry with respect to the optical axis Ax at any position along the optical axis Ax, the light sources of the two light fluxes are positioned in point symmetry with the optical axis Ax as a point of symmetry.

In summary, by arranging the plurality of emitting ends in the light emitting area EA1 in point symmetry with the optical axis Ax as a point of symmetry, the plurality of light fluxes emitted from the plurality of emitting ends can be entered into the fly-eye lens 5 symmetrically, and thus the plurality of illuminance distributions formed by the plurality of light fluxes emitted from the plurality of emitting ends can be dispersed to positions in point symmetry with the position of the optical axis Ax as a point of symmetry. As a result, the peaks of the illuminance distributions each having the arch shape are dispersed appropriately, and the illuminance distribution is uniformized as a whole.

In the first embodiment, based on the above findings of the inventor of the present application, the set of the plurality of emitting ends 1L of the large diameter fibers 1L, the set of the plurality of emitting ends 1Me of the medium diameter fibers 1M, and the set of the plurality of emitting ends 1Se of the small diameter fibers 1S are each arranged in point symmetry with the optical axis Ax as a point of symmetry, in the light emitting area EA1 of the light source unit LS1. As a result, the illuminance distribution in the illumination area ILA will be uniformized in each of the cases where the σ value is set to “large”, “medium”, and “small”.

Meanwhile, the illuminance distribution may be changed, treating the illuminance distribution as one of the illumination conditions.

In the illumination optical system IL1 of the first embodiment, the illuminance distribution in the illumination area ILA can be changed by individually adjusting the output power of each of the three semiconductor lasers included in the semiconductor laser unit 2. For example, if the output power of each of the three semiconductor lasers included in the semiconductor laser unit 2 is individually adjusted in a case where the illumination under the illumination condition of σ=“large” is performed, the light intensity balance between light emitted from the plurality of emitting ends 1Le changes, and thus the illuminance distribution in the illumination area ILA changes. The illuminance distribution in the illumination area ILA will be changed in a manner the same as above in each of the illuminations under the illumination conditions of σ=“medium” and σ=“small”. Note that, correction of illuminance inclination, correction of illuminance curve may be performed as the change of the illuminance distribution. Regarding illuminance distributions in FIG. 8B, the solid line indicates the illuminance distribution obtained in a case where the output powers of the three semiconductor lasers are equal to each other, and the dotted line indicates the illuminance distribution obtained in a case where the inclination component of the illuminance is corrected by increasing the output power of the semiconductor laser corresponding to the right emitting end 1Le in FIG. 2 and decreasing the output power of the semiconductor laser corresponding to the left emitting end 1Le in FIG. 2.

In this modification, a film thickness sensor (not depicted) configured to measure a film thickness of the photosensitive resist coated on the substrate P may be disposed in the Exposure apparatus EX. In this case, for example, the controller CONT1 sends the film thickness of the resist measured by the film thickness sensor to the controller CONT2 of the illumination optical system IL1. The controller CONT2 controls the illumination optical system ILI based on the film thickness information received from the controller CONT1, and changes the illuminance distribution in the illumination area ILA to an appropriate distribution according to the film thickness of the resist on the substrate P being an object of the exposure.

Specifically, for example, the controller CONT2 may receive information on the unevenness of the film thickness of the photosensitive resist coated on the substrate P onto which the exposure will be performed next from the controller CONTI of the exposure apparatus before the exposure, and apply unevenness to the illuminance distribution in the illumination area ILA such that the exposure amount to the portion having large film thickness will be large. By doing so, the exposure amount per unit volume of the resist will be uniformized, and more suitable development result (resist image) will be obtained. More specifically, for example, difference in average film thicknesses among the plurality of substrates P will be compensated, and line width stability will be obtained among the plurality of substrates P.

Other than the above, the controller CONT2 may change the illuminance distribution according to the line width of the pattern MP of the mask M, and may change the illuminance distribution such that the uniformity of the line width is further increased based on the result of the measurement of the uniformity of the line width of the resist layer to which the exposure and the development have already been performed. Further, the change of the illuminance distribution by the controller CONT2 is not limited to the change performed before the exposure, but may be the change performed during the scanning exposure. In this case, for example, the controller CONT2 obtains the information on the film thicknesses (e.g., the film thicknesses will be measured before the exposure by the film thickness sensor disposed in the exposure apparatus) at a plurality of (a number of) points in the substrate P from the controller CONT1, and successively changes the illuminance distribution during the scanning exposure to the illuminance distribution according to the film thickness at the exposure objective position. That is, the illuminance distribution is changed during a period in which the illumination optical system IL1 performs irradiation of the illumination light to expose the pattern MP onto one substrate P via the projection optical system PL so as to change the condition of the exposure to the substrate P to which the transferring is performed. By doing so, for example, the unevenness of the film thickness of the resist can be compensated in one substrate P and the line width uniformity can be obtained in one substrate P.

The controller CONT1 (or any other controller) of the exposure apparatus EX may adjust the illuminance distribution of another illumination optical systems IL1 included in the illumination unit IU referring to the illuminance distribution of a certain illumination optical system IL1 included in the illumination unit IU. Specifically, for example, in order to perform the irradiation of the illumination light to a certain overlap area OR appropriately, illuminance distribution of one illumination optical system IL1 configured to irradiate the certain overlap area OR with illumination light may be changed referring to illuminance distribution of the other illumination optical system configured to irradiate the certain overlap area OR with illumination light.

Note that, in some cases, the photosensitive property of the resist may not be proportional only to the exposure amount expressed as “illuminance” x “exposure time” (i.e., the product of “illuminance” times “exposure time”). In such cases, if the exposure is performed divided into multiple times, the illuminance distribution may be changed to compensate for the illuminance.

The effects of the illumination optical system IL1 and the exposure apparatus EX of the first embodiment will be summarized below.

The illumination optical system IL1 of the first embodiment can change the dimension itself of the light flux emitted from the light source unit LS1, and thus can change the illumination condition (σ value) without shielding a part of the light flux. In other words, the illumination condition can be changed without causing loss of light intensity.

The illumination optical system IL1 of the first embodiment can change the dimension itself of the light flux emitted from the light source LS1, and thus can change the illumination condition (σ value) without disposing a complex structure, such as a variable aperture stop, including a moving mechanism at a position near the irradiation objective surface. This is particularly advantageous in a case where the illumination unit IU including many illumination optical systems IL1 is constructed; and the illumination unit IU and consequently the exposure apparatus EX will be small sized as a result.

The illumination optical system ILI of the first embodiment irradiates the illumination area ILA with all of the light emitted from the semiconductor laser unit 2, regardless of the value of the o value. Thus, the o value can be changed while maintaining the light intensity of the light with which to the irradiation objective surface is irradiated. In contrast, in the conventional technique, the light intensity decreases because small σ is realized by shielding the light flux by the aperture stop.

The illumination optical system IL1 of the first embodiment can change the illuminance distribution in the illumination area ILA. Therefore, the illumination optical system IL1 can realize more suitable illumination condition according to the conditions of the mask M and the substrate P, by changing the illuminance distribution according to the mask pattern MP and/or the condition of the resist coated on the substrate P. In addition, since the set of the plurality of emitting ends 1Le, the set of the plurality of emitting ends 1Me, and the set of the plurality of emitting ends 1Se are each arranged in the light emitting area EA1 in point symmetry with the optical axis Ax as a point of symmetry, the illuminance distribution with high uniformity can be realized.

The illumination optical system IL1 of the first embodiment includes the optical fiber group 1, and the emitting end of each optical fiber included in the optical fiber group 1 is arranged in the light emitting area EA1. Therefore, the semiconductor laser unit 2 that is relatively large and requires a cooling mechanism, and/or the moving mechanism 21 that can be a complex structure, can be disposed in a relatively spacious location away from the illumination area ILA. In addition, the illumination optical system IL1 of the first embodiment can uniformize the light intensity distribution of the light emitted from the semiconductor laser unit 2 in the optical fiber.

The exposure apparatus EX of the first embodiment can transfer various patterns MP of the mask M onto the substrate P suitably, while changing the illumination condition easily and suitably by using the illumination optical system IL1.

### Modification of First Embodiment

To the illumination optical system IL1 of the first embodiment, the following modification can be applied.

In the light source unit LS1 of the illumination optical system IL1 of the first embodiment, the size of the incidence area of the light flux (dimension of the cross section) in the incidence surface 5i of the fly-eye lens 5 is switched by using three types of optical fibers of which core diameter is different from each other so as to switch the o value. However, such configuration is not exclusive.

Specifically, for example, in the fiber group 1, each of the large diameter fibers 1L and the small diameter fibers 1S may be replaced by the medium diameter fiber 1M. In this case, the arrangement of the fiber end faces in the light emitting area EA1 viewed in the direction of the optical axis Ax may be the same as the arrangement in the first embodiment (FIG. 4), except that the sizes of the fiber end faces are the same as each other among all of the fiber end faces. On the other hand, the positions of the fiber end faces in the direction of the optical axis Ax may be different from each other.

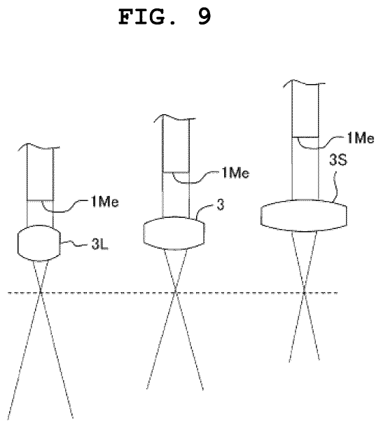

Among the twenty seven emitting ends 1Me arranged in such a manner, regarding the emitting end 1Me located at the position where the emitting end 1Me of the middle diameter fiber 1M is arranged in the first embodiment, the collector lens 3 is used (FIG. 9), like the first embodiment.

On the other hand, regarding the emitting end 1Me (left end in FIG. 9) located at the position where the emitting end 1Le of the large diameter fiber 1L is located in the first embodiment, the position of the emitting end in the direction of the optical axis Ax is made closer to the relay lens 4 compared to the emitting end 1Me located at the position where the emitting end 1Me of the middle diameter fiber 1M is located in the first embodiment as well. Further, the collector lens 3 is replaced by a collector lens 3L with a smaller focal length (smaller radius of curvature) compared to the collector lens 3. The collector lens 3L is arranged so that the front focal point of the collector lens 3L is located on the corresponding emitting end 1Me. The diameter of the light flux emitted from the collector lens 3L is larger than the diameter of the light flux emitted from the collector lens 3 at the incidence surface 5i of the fly-eye lens 5.

Similarly, regarding the emitting end 1Me (right end in FIG. 9) located at the position where the emitting end 1Se of the small diameter fiber 1S is located in the first embodiment, the position of the emitting end in the direction of the optical axis Ax is made farther from the relay lens 4 compared to the emitting end 1Me located at the position where the emitting end 1Me of the middle diameter fiber 1M is located in the first embodiment as well. Further, the collector lens 3 is replaced by a collector lens 3S with a larger focal length (larger radius of curvature) compared to the collector lens 3. The collector lens 3S is arranged so that the front focal point of the collector lens 3S is located on the corresponding emitting end 1Me. The diameter of the light flux emitted from the collector lens 3S is smaller than the diameter of the light flux emitted from the collector lens 3 in the incidence surface 5i of the fly-eye lens 5.

As depicted in FIG. 9, in the modification, the rear focal point of each of the collector lens 3L, the collector lens 3, and the collector lens 3S coincides or substantially coincides with the position of the front focal point of the relay lens 4. This allows the o value to be changed without changing the focus position of the light source image.

In this modification, the core diameters of the optical fibers included in the fiber group 1 is made uniform, but the focal lengths and the arrangements of the collector lenses corresponding to the emitting ends of the optical fibers are varied. In the modification, the size of the incidence area (dimension of the cross section) of the light flux at the incidence surface 5i of the fly-eye lens 5 can be switched by moving the semiconductor laser unit 2, and thus the magnitude of the σ value can be switched.

The illumination optical system IL1 of the first embodiment has a configuration in which three types of o value can be selected. However, such configuration is not exclusive. The illumination optical system IL1 may be configured such that only two types of o value can be selected, by removing for example the small diameter fibers 1S from the fiber group 1. Alternatively, the illumination optical system IL1 may be configured such that four or more types of o value can be selected, by adding the optical fiber(s) having the core diameter different from those of the large diameter fiber 1L, the medium diameter fiber 1M, and the small diameter fiber 1S to the fiber group 1. The illumination optical system IL1 of the first embodiment has a configuration in which the σ value can be selected from the values of three types. However, such configuration in not exclusive. The illumination optical system IL1 of the first embodiment may have a configuration in which a relay optical system configured to zoom a diameter of light from the fiber exiting end is added at a position between the collector lens 3 and the relay lens 4. With such a relay optical system, the dimension of the cross section of the light flux at the incidence surface 5i of the fly-eye lens 5 can be changed continuously, and thus the o value can be changed continuously. In this case, the fiber of one type or the fibers of two types among the large diameter fiber 1L, the medium diameter fiber 1M, and the small diameter fiber 1S of the fiber group 1 may be omitted.

### Second Embodiment

The illumination optical system IL2 of the second embodiment will be described with reference to FIG. 10 to FIG. 14.

The illumination optical system IL2 of the second embodiment is identical to the illumination optical system IL1 of the first embodiment, except that the configuration of the light source unit LS2 is different from the configuration of the light source unit LS1 of the illumination optical system IL1 of the first embodiment. Among the components of the illumination optical system IL2, those the same as the components of the illumination optical system IL1 will not be described.

### Light Source Unit LS2

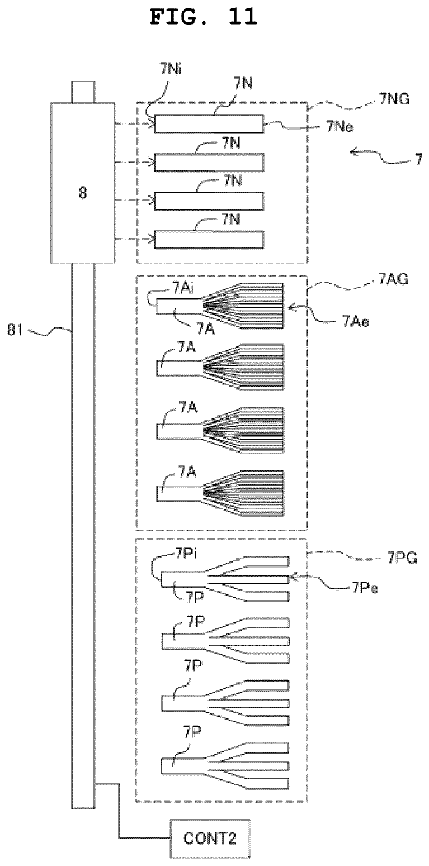

As depicted in FIG. 10 and FIG. 11, the light source unit LS2 mainly includes an optical fiber (light guide) group 7, a semiconductor laser unit (source, light source device) 8, a plurality of collector lenses 9, and a controller (illuminance distribution controller) CONT2.

As depicted in FIG. 11, the optical fiber group 7 includes a normal illumination fiber group 7NG including a plurality of normal illumination fibers 7N, an annular illumination fiber group 7AG including a plurality of annular illumination fibers 7A, and a quadrupole illumination fiber group 7PG including a plurality of quadrupole illumination fibers 7P.

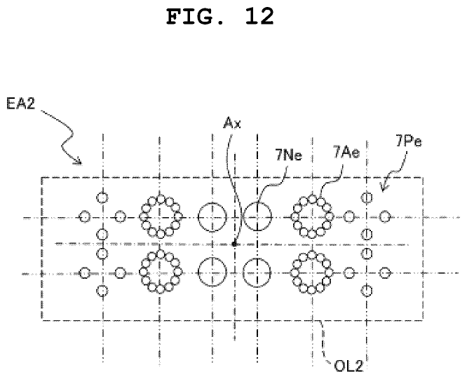

Each of the plurality of normal illumination fibers 7N included in the normal illumination fiber group 7NG has an incidence end 7Ni into which light from the semiconductor laser unit 8 enters and an emitting end 7Ne configured to emit the light entered into the normal illumination fiber 7N. Each of the fibers 7N has one emitting end 7Ne with respect to one incidence end 7Ni. The shape of the cross section of the emitting end 7Ne is s circle (FIG. 12).

Each of the plurality of annular illumination fibers 7A included in the annular illumination fiber group 7AG has an incidence end 7Ai into which light from the semiconductor laser unit 8 enters and an emitting end 7Ae configured to emit the light entered into the annular illumination fiber 7A. Each of the annular illumination fibers 7A branches into may parts on the path from the incidence end 7Ai to the emitting ends 7Ae. At the emitting end 7Ae, many fiber end faces each having circular shape are arranged in an annular shape (FIG. 12).

Each of the plurality of quadrupole illumination fibers 7P included in the quadrupole illumination fiber group 7PG has an incidence end 7Pi into which light from the semiconductor laser unit 8 enters and an emitting end 7Pe configured to emit the light entered into the quadrupole illumination fiber 7P. Each of the plurality of quadrupole illumination fibers 7P branches into four parts in the path from the incidence end 7Pi to the emitting end 7Pe. At the emitting end 7Pe, four fiber end faces each having circular shape are arranged at equal intervals along a circle (FIG. 12).

In order to avoid complication of the drawings, only one normal illumination fiber 7N, only one annular illumination fiber 7A, and only one quadrupole illumination fiber 7P are depicted in each of FIG. 10, FIG. 13, and FIG. 14.

The respective emitting ends 7Ne of the normal illumination fibers 7N, the respective emitting ends 7Ae of the annular illumination fibers 7A, and the respective emitting ends 7Pe of the quadrupole illumination fibers 7P are all configured to be flat. As depicted in FIG. 12, the emitting ends 7Ne, 7Ae, and 7Pe are arranged flush with each other in a plane orthogonal to the optical axis Ax of the illumination optical system IL2. Here, the planar area in which the emitting ends 7Ne, 7Ae, and 7Pe are arranged flush with each other is referred to as a light emitting area EA2. Note that, if the focal lengths of the plurality of collector lenses 9 corresponding to the emitting ends 7Ne, 7Ae, and 7Pe, respectively, are different from each other, the positions of the emitting ends 7Ne, 7Ae, and 7Pe in the Z direction may be different from each other. In this case, the positions in the direction of the optical axis Ax of the rear focal points of the plurality of collector lenses 9 having different focal lengths from each other coincide or substantially coincide with each other, and the position in the direction of the optical axis Ax of the front focal point of each of the plurality of collector lenses 9 having different focal lengths from each other coincides or substantially coincides with the position in the direction of the optical axis Ax of any of the emitting ends 7Ne, 7Ae, and 7Pe.

In the light emitting area EA2, the emitting ends 7Ne of the normal illumination fibers 7N are arranged in a matrix with two rows in the X direction and two columns in the Y direction. In both the X direction and the Y direction, the middle position of the two exit ends 7Ne is the same as the position of the optical axis Ax.

The emitting ends 7Ae of the annular illumination fibers 7A is arranged in a matrix with two rows in the X direction and two columns in the Y direction, the emitting ends 7Ne of the normal illumination fibers 7N being interposed between the emitting ends 7Ae. In both the X direction and the Y direction, the middle position of the two emitting ends 7Ae is the same as the position of the optical axis Ax.

The emitting ends 7Pe of the quadrupole illumination fibers 7P are arranged in a matrix with two rows in the X direction and two columns in the Y direction, the emitting ends 7Ae of the annular illumination fibers 7A being interposed between the emitting ends 7Pe. In both the X direction and the Y direction, the middle position of the two emitting ends 7Pe is the same as the position of the optical axis Ax.

In such a manner, in the light emitting area EA2, the set of the emitting ends 7Ne of the four normal illumination fibers 7N, the set of the emitting ends 7Ae of the four annular illumination fibers 7A, and the set of the emitting ends 7Pe of the four quadrupole illumination fibers 7P are each arranged in point symmetry with the position of the optical axis Ax (optical axis of the relay lens 4) as a point of symmetry.

In this embodiment, the plurality of emitting ends 7Ne is arranged in point symmetry with respect to the optical axis Ax, and at the same time, the plurality of emitting ends 7Ne is arranged in line symmetry with respect to a reference line extending in the X direction through the optical axis Ax and in line symmetry with respect to a reference line extending in the Y direction through the optical axis Ax. The same is true for each of the plurality of emitting ends 7Ae and the plurality of emitting ends 7Pe. In such a manner, the plurality of emitting ends of the same type may be arranged in line symmetry with respect to the reference line extending in the X direction through the optical axis Ax and/or the reference line extending in the Y direction through the optical axis Ax, rather than in point symmetry with respect to the optical axis Ax.

The semiconductor laser unit 8 includes four semiconductor lasers (laser diodes), and is configured to emit light flux from each semiconductor laser, the light fluxes being emitted in parallel with each other from positions different from each other.

The semiconductor laser unit 8 is moved by the moving mechanism 81 so as to enter the light fluxes from the four semiconductor lasers into the four incidence ends 7Ni included in the normal illumination fiber group 7NG, the four incidence ends 7Ai included in the annular illumination fiber group 7AG, or the four incidence ends 7Pi included in the quadrupole illumination fiber group 7PG.

The light entered into each of the incidence ends 7Ni repeats internal reflection in each of the normal illumination fibers 7N, and then emitted from each of the emitting ends 7Ne arranged in the light emitting area EA2 with a light intensity distribution being substantially uniform. The same is true for the light entered into each of the incidence ends 7Ai and the light entered into each of the incidence ends 7Pi.

One collector lens 9 is disposed for each of the four emitting ends 7Ne, each of the four emitting ends 7Ae, and each of four emitting ends 7Pe, and twelve collector lenses 9 in total are disposed. The collector lens 9 corresponding to the emitting end 7Ne is disposed such that the optical axis of the collector lens 9 coincides or substantially coincides with the center of the core at the emitting end 7Ne. The collector lens 9 corresponding to the emitting end 7Ae is disposed such that the optical axis of the collector lens 9 coincides or substantially coincides with the center of the annular shape at the emitting end 7Ae. The collector lens 9 corresponding to the emitting end 7Pe is disposed such that the optical axis of the collector lens coincides or substantially coincides with the center of the four circular emitting ends at the emitting end 7Pe. In FIG. 12, the position at which the alternate long and two short dashes lines cross indicates the position of the optical axis of the collector lens 9.

Each of the collector lenses 9 is disposed such that the optical axis of the collector lens 9 is parallel or substantially parallel to the optical axis Ax (being identical to the optical axis of the relay lens 4) of the illumination optical system IL2. Each of the collector lenses 9 is disposed such that the position of the front focal point of the collector lens 9 coincides or substantially coincides with the position of the light emitting area EA2 (i.e., the plane in which the emitting ends 7Ne, 7Ae and 7Pe are arranged flush with each other) in the direction of the optical axis Ax.

### Shape Changed Illumination

Next, the changing of the illumination condition in the illumination optical system IL2 of the second embodiment, specifically the switching among normal illumination, annular illumination, and quadrupole illumination, will be described.

In a case where the normal illumination is preformed, the controller CONT2 moves the semiconductor laser unit 8 such that the light fluxes from the semiconductor laser unit 8 enter into the normal illumination fiber group 7NG and the light fluxes are emitted from the emitting ends 7Ne of the normal illumination fibers 7N in the light emitting area EA2 (FIG. 10A). The light fluxes emitted from the four emitting ends 7Ne enter the identical area on the incidence surface 5i of the fly-eye lens 5 overlapping with each other, via the collector lenses 9 corresponding respectively thereto and the relay lens 4.

The area ARN in the incidence surface 5i (an aggregate of the rectangular incidence surfaces 5ai of the lens elements 5a) of the fly-eye lens 5 into which the light fluxes emitted from the four emitting ends 7Ne enter overlappingly is a circular area substantially inscribed in the substantially square outline of the incidence surface 5i (FIG. 10B).

As described above, the light intensity distribution of the light flux entering into the incidence surface 5i of the fly-eye lens 5 is reflected in the light intensity distribution in the emitting surface 5e of the fly-eye lens 5. Thus, a circular pupil intensity distribution is formed in the illumination pupil PP near the emitting plane 5e of the fly-eye lens 5 and the normal illumination is performed.

In a case where the annular illumination is preformed, the controller CONT2 moves the semiconductor laser unit 8 such that the light fluxes from the semiconductor laser unit 8 enter into the annular illumination fiber group 7AG and the light fluxes are emitted from the emitting ends 7Ae of the annular illumination fibers 7A in the light emitting area EA2 (FIG. 13A). The light fluxes emitted from the four emitting ends 7Ae enter the identical area on the incidence surface 5i of the fly-eye lens 5 overlapping with each other, via the collector lenses 9 corresponding respectively thereto and the relay lens 4.

The area ARA in the incidence surface 5i of the fly-eye lens 5 into which the light fluxes emitted from the four emitting ends 7Ae enter overlappingly is an annular area substantially inscribed in the substantially square outline of the incidence surface 5i (FIG. 13B). Thus, an annular pupil intensity distribution is formed in the illumination pupil PP near the emitting surface 5e of the fly-eye lens 5 and the annular illumination is performed.

In a case where the quadrupole illumination is preformed, the controller CONT2 moves the semiconductor laser unit 8 so that the light fluxes from the semiconductor laser unit 8 enter into the quadrupole illumination fiber group 7PG and the light fluxes are emitted from the emitting ends 7Pe of the quadrupole illumination fibers 7P in the light emitting area EA2 (FIG. 14A). The light fluxes emitted from the four emitting ends 7Pe enter the identical area on the incidence surface 5i of the fly-eye lens 5 overlapping with each other, via the collector lenses 9 corresponding respectively thereto and the relay lens 4.

The area ARP in the incidence surface 5i of the fly-eye lens 5 into which the light fluxes emitted from the four emitting ends 7Pe enter overlappingly is four circular areas located at equal intervals along a circle of which center is the optical axis Ax (FIG. 14B). Thus, an quadrupole pupil intensity distribution is formed in the illumination pupil PP near the emitting surface 5e of the fly-eye lens 5 and the quadrupole illumination is performed.

In such a manner, in the illumination optical system IL2 of the second embodiment, the change of the illumination condition, that is the switching among the normal illumination, the annular illumination, and the quadrupole illumination, can be performed by switching the emitting end that emits light in the light emitting area EA2, and consequently changing the shape of the cross section of the light flux at the incidence surface 5i of the fly-eye lens 5.

Like the illumination optical system IL1 of the first embodiment, the illumination optical system IL2 of the second embodiment can change the illuminance distribution in the illumination area ILA by individually adjusting the output powers of the four semiconductor lasers of the semiconductor laser unit 8 so as to change the light intensity balance of the light emitted from the plurality of emitting ends 7Ne, the light intensity balance of the light emitted from the plurality of emitting ends 7Ae, or the light intensity balance of the light emitted from the plurality of emitting ends 7Pe. The illumination optical system IL2 of the second embodiment can be used together with the film thickness sensor of the exposure apparatus EX. In this case, for example, the controller CONT1 sends the measured film thickness of the resist to the controller CONT2 of the illumination optical system IL2. The controller CONT2 controls the illumination optical system IL2 based on the film thickness information received from the controller CONT1 and changes the illuminance distribution in the illumination area ILA to an appropriate distribution according to the film thickness of the resist on the substrate P being an object of the exposure.

The effects of the illumination optical system IL2 of the second embodiment will be summarized below.

In the illumination optical system IL2 of the second embodiment, like the illumination optical system IL1 of the first embodiment, the illumination conditions can be changed without causing loss of light intensity and without disposing a complex structure including a moving mechanism at a position near the irradiation objective surface. In addition, the illumination optical system IL2 of the second embodiment can switch between the normal illumination, the annular illumination, and the quadrupole illumination while maintaining the light intensity of the light with which the irradiation objective surface is irradiated at a constant level.

Like the illumination optical system ILI of the first embodiment, the illumination optical system IL2 of the second embodiment can realize more suitable illumination condition according to the state of the mask M and/or the substrate P, and can realize the illuminance distribution with high uniformity, by changing the illuminance distribution.

### Modification of Second Embodiment

To the illumination optical system IL2 of the second embodiment, the following modification can be applied.

In the light source unit LS2 of the illumination optical system IL2 of the second embodiment, the annular illumination is performed by using the annular illumination fiber 7A. However, such configuration is not exclusive.

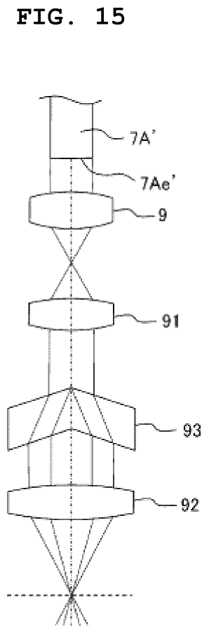

Specifically, for example, as depicted in FIG. 15, the annular illumination fiber 7A may be replaced with an optical fiber 7A′ that has no branch and has a single circular incidence end and a single circular emitting end like the normal illumination fiber 7N. A first relay lens 91, a second relay lens 92, and an axicon lens 93 may be arranged downstream of the emitting end 7Ae′ of the optical fiber 7A′ and the collector lens 9 in the optical path of the light exiting from the emitting end 7Ae′.

The condenser lens 9 is arranged such that the optical axis of the condenser lens 9 is parallel or substantially parallel to the optical axis Ax and the front focal point of the condenser lens 9 is located on or near the emitting end 7Ae′. The first relay lens 91, the axicon lens 93, and the second relay lens 92 are arranged substantially on a single straight line such that the optical axis of the first relay lens 91, the optical axis of the axicon lens 93 and the optical axis of the second relay lens 92 are each parallel or substantially parallel to the optical axis Ax. Furthermore, the position of the front focal point of the first relay lens 91 is located near the position of the rear focal point of the collector lens 9, and the first relay lens 91 forms an image of the emitting end 7Ae′ at a position near the axicon lens 93.

In this configuration, the light emitted from the emitting end 7Ae′ of the optical fiber 7A′ is converted to the light having an annular cross section via the collector lens 9, the first relay lens 91, and the axicon lens 93. Then the light enters into the annular area ARA in the incidence surface 5i of the fly-eye lens 5 via the second relay lens 92 and the relay lens 4.

The illumination optical system IL2 of the second embodiment has a configuration by which the switching among the normal illumination, the annular illumination, and the quadrupole illumination can be performed. However, such configuration is not exclusive. The illumination optical system IL2 of the second embodiment may be configured, for example, to be capable of selecting two types of illumination, that is the normal illumination and the annular illumination, by removing the quadrupole illumination fiber 7P. Alternatively, the illumination optical system IL2 of the second embodiment may be configured to be capable of selecting the double-pole illumination, by adding the double-pole illumination fiber to the fiber group 7. That is, the illumination optical system IL2 of the second embodiment may be configured in various aspects each capable of selecting a plurality of types of illumination condition.

### Modification of the First and Second Embodiments

To the illumination optical system IL1 of the first embodiment and the illumination optical system IL2 of the second embodiment, the following modification can be applied.

The illumination optical system IL1 of the first embodiment and the illumination optical system IL2 of the second embodiment can be combined in any manner to form an illumination optical system in which any illumination condition can be selected. Specifically, for example, the medium diameter fiber group 1 MG of the illumination optical system IL1 may be replaced with the annular illumination fiber group 7AG of the illumination optical system IL2 so as to obtain the illumination optical system in which the illumination condition can be switched among σ value=“large”, σ value=“small”, and the annular illumination.

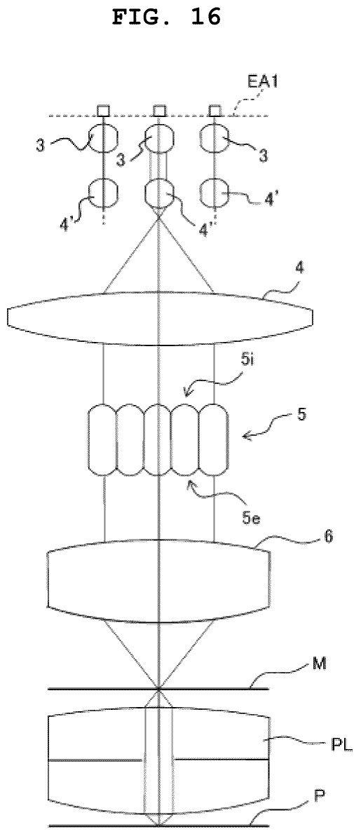

The illumination optical system IL1, IL2 of the first, second embodiment is configured so that the image of the emitting end of the optical fiber arranged in the light emitting area EA1, EA2 is formed at a position near the incidence surface 5i of the fly-eye lens 5. However, such configuration is not exclusive. The illumination optical system IL1, IL2 of the first, second embodiment may be configured such that the image of the emitting end of the optical fiber arranged in the light emitting area EA1, EA2 is formed at a position near the emitting surface 5e of the fly-eye lens 5. Such an optical system may have a configuration, specifically for example, in which an additional relay lenses 4′ are added between the collector lenses 3 and the relay lens 4 (FIG. 16).

In the illumination optical system IL1 having such a configuration, the σ value can be changed by switching the emitting end which emits the light in the light emitting area EA1 and consequently changing the dimension of the cross section of the light flux at the incidence surface 5i of the fly-eye lens 5. In the illumination optical system IL2 having such a configuration, the change of the illumination condition, that is the switching between the normal illumination, the annular illumination, and the quadrupole illumination, can be performed by switching the emitting end which emits the light in the light emitting area EA2, and consequently changing the shape of the cross section of the light flux at the incidence surface 5i of the fly-eye lens 5. In the case of quadrupole illumination, diffractive optical element(s) or the like may be inserted into a position between the collector lenses 3 and the relay lens 4.

In the illumination optical systems IL1, IL2 of the first, second embodiment, the illuminance distribution in the illumination area ILA is changed by changing the output power balance of the plurality of semiconductor lasers included in the semiconductor laser unit 2, 8. However, such configuration is not exclusive.

Specifically, for example, an optical fiber may be added to at least one of the large diameter fiber group 1LG, the medium diameter fiber group 1MG, and the small diameter fiber group 1SG included in the fiber group 1, and the normal illumination fiber group 7NG, the annular illumination fiber group 7AG, and the quadrupole illumination fiber group 7PG included in the fiber group 7, to increase the number of optical fibers constituting the fiber group. The incidence end of the added optical fiber may be arranged at a position where light from the semiconductor laser unit 2 can enter the incidence end by moving the semiconductor laser unit 2. The emitting end of the added optical fiber may be arranged at a position between the existing emitting ends in the light emitting area EA1, EA2. Specifically, for example, an additional large diameter fiber 1L may be added to the large diameter fiber group 1LG of the first embodiment, and the emitting end 1Le of the additional large diameter fiber 1L may be arranged at a position different from the emitting ends 1Le depicted in FIG. 4.

As a result, the fiber group in which the number of the optical fibers has been increased will have an additional optical fiber. This means that, for example, in the case of the large diameter fiber group 1LG, the emitting end which emits the light in the light emitting area EA1 can be changed from the emitting ends 1Le depicted in FIG. 3 to the emitting end 1Le of the additional large diameter fiber 1L, by changing the incidence end into which the light from the semiconductor laser unit 2 enters from the incidence ends 1Li depicted in FIG. 3 to the incidence end 1Li of the additional large diameter fiber 1L.

Since the light from the emitting end 1Le of the additional large diameter fiber 1L is emitted from a position in the light emitting area EA1, EA2 different from the positions of the existing emitting ends (i.e., the emitting ends 1Le depicted in FIG. 4), the light enters into the incidence surface 5i of the fly-eye lens 5 at an angle different from the angle defined in a case of the light from the existing emitting end, and forms an illuminance distribution, in the illumination area ILA, different from the illuminance distribution formed by the light from the existing emitting ends. Therefore, the controller CONT2 can change the illuminance distribution in the illumination area ILA by changing the incidence end into which the light from the semiconductor laser unit 2 enters among the incidence ends 1Li, and consequently changing the position of the emitting end 1Le which emits the light in the light emitting area EA1. Since the switching is performed within the large diameter fiber group 1LG, the illumination condition of σ value=“large” is maintained.

Although the description is made regarding the example in which the additional optical fiber is added to the large diameter fiber group 1LG, the same modification can be applied to other fiber groups such as the medium diameter fiber group 1MG and the like.

As another method of changing the illuminance distribution in the illumination area ILA, an moving mechanism may be added to move at least one of the emitting ends 1Le, 1Me, 1Se arranged in the light emitting area EA1 in the X direction and the Y direction together with the corresponding collector lens 3. Further, an moving mechanism may be added to move at least one of the emitting ends 7Ne, 7Ae, 7Pe arranged in the light emitting area EA2 in the X direction and the Y direction together with the corresponding collector lens 9.

In those configurations, by moving a pair of at least one of the emitting ends in the light emitting area EA1, EA2 and the corresponding collector lens with respect to the optical axis Ax of the illumination optical system IL1, IL2, the incidence angle to the fly-eye lens 5 is changed, and consequently the illuminance distribution in the illumination area ILA is changed.

As another method of changing the illuminance distribution in the illumination area ILA, a configuration in which the optical axis of at least one of the collector lenses 3 and the center of the core of the corresponding emitting end 1Le, 1Me, 1Se are shifted (eccentric) from each other can be used. In this configuration, the incidence angle of the light transmitted through the collector lens 3 to the incidence surface 5i of the fly-eye lens 5 can be changed by rotating the emitting end eccentrically arranged with respect to the optical axis of the collector lens 3 around the optical axis of the collector lens 3. Other than the above aspects, by adding an moving mechanism configured to change the positional relationship between the collector lens 3, 9 and the corresponding emitting end and by moving at least one of the collector lens 3, 9 and the corresponding emitting end in a direction orthogonal to the optical axis of the collector lens 3, 9, the incidence angle of the light transmitted through the collector lens 3, 9 to the fly-eye lens 5 can be changed, and consequently the illuminance distribution in the illumination area ILA can be changed.

As another method of changing the illuminance distribution in the illumination area ILA, a bending mechanism configured to change a curvature of the optical fiber (that is, the mechanism configured to physically bend the optical fiber) may be added. In this configuration, the curvature of at least one of the large diameter fiber 1L, the medium diameter fiber 1M, and the small diameter fiber 1S included in the fiber group 1, or the curvature of at least one of the normal illumination fiber 7N, the annular illumination fiber 7A, and the quadrupole illumination fiber 7P included in the fiber group 7 is changed at a position near the emitting end. By doing so, the incidence angle to the fly-eye lens 5 of the light transmitted through the corresponding collector lens 3, 9 can be changed, and the illuminance distribution of the illumination area ILA can be changed.

As a method of changing a distribution of the incidence angle to the illumination area ILA, in the conventional example, the illumination optical system aperture stop located at the pupil conjugate plane is moved in the direction orthogonal to the optical axis. However, since the above embodiments do not have an illumination system aperture stop, such adjustment as in the conventional example is difficult to adopt. Therefore, in the above embodiments, the entire of the light source unit LS1, LS2 may be tilted relative to the relay lens 4 in the X direction or the Y direction by an moving mechanism. Alternatively, a prism pair (a dove prism pair or a wedge prism pair) may be arranged between the light source unit LS1, LS2 and the relay lens 4. In this configuration, the light intensity distribution at the emitting end of the fly-eye lens 5 can be changed and consequently the distribution of the incidence angle to the illumination area ILA can be changed, by changing the positional relationship between the prisms constructing the prism pair to change the direction of the light exiting the light source unit LS1, LS2 and shift the position of the light flux entering into the fly-eye lens 5.

In the illumination optical system IL1, IL2 of the first, second embodiment, the semiconductor laser unit 2, 8 is moved by the moving mechanism 21, 81 to switch the fiber group into which the light from the semiconductor laser unit 2, 8 enters. However, such configuration is not exclusive. The configuration may be as follows. That is, one semiconductor laser unit is disposed for each of a plurality of fiber groups, such as the large diameter fiber group 1LG, etc., and the light is caused to enter into the desired fiber group by switching the semiconductor laser unit 2 to be activated.

In the illumination optical system IL1 of the first embodiment and the illumination optical system IL2 of the second embodiment, a light emitting diode unit including a plurality of light emitting diodes (LEDs) can be used instead of the semiconductor laser unit 2, 8. The light emitting diode unit may be configured to be moved by the moving mechanism 21, 81 to cause the light from the light emitting diode unit to enter into a desired fiber group within a plurality of fiber groups such as the large diameter fiber group 1LG, etc. Alternatively, the configuration may be as follows. That is, the light emitting diode is disposed individually to each of the fibers of the plurality of fiber groups, such as the large diameter fiber group 1LG, etc., and the light is caused to enter into the desired fiber group by switching the light emitting diode that emits the light.

Other than the above, a unit including a plurality of desired light sources of, such as a fiber laser, a mercury lamps, etc., instead of the semiconductor laser unit 2, 8 can be used.

In the illumination optical system IL1 of the first embodiment and the illumination optical system IL2 of the second embodiment, an input lens configured to cause light from the light source device to enter into each fiber may be disposed at a position between the light source device such as the semiconductor laser unit 2 etc. and the incidence end of each of the optical fibers of the fiber group 1. The optical fibers of the fiber group 1 may be configured such that the numerical apertures of the fibers are the same as each other at the incidence end.

In the illumination optical systems IL1, IL2 of the first and second embodiments, the fiber group 1 may be omitted, and light emitting diodes (an example of a solid state light source) having light emitting surfaces of which shapes are the same as the shape of the emitting end 1Le, 7Ne, etc., may be arranged at the positions in the light emitting area EA1, EA2 where the emitting end 1Le, 7Ne, etc. are arranged, in a manner as depicted in FIG. 4 and FIG. 12. In this configuration, by switching the light emitting diodes which emits the light in the light emitting area EA1, EA2, the shape of the light emitting surface in the light emitting area EA1, EA2 can be changed, and consequently the shape of the image of the light emitting surface to be projected onto the incidence surface 5i of the fly-eye lens 5 can be changed. Similarly, the light emitting surfaces of a semiconductor laser (an example of a solid state light source) can be arranged in the light emitting area EA1, EA2. In this configuration, the light emitting surface of the light emitting diode or semiconductor laser is an example of “light emitting surface”.

The illumination optical system ILI of the first embodiment has six emitting ends 1Le for realizing the illumination condition of σ=“large”, nine emitting ends 1Me for realizing the illumination condition σ=“medium”, and twelve emitting ends 1Se for realizing the illumination condition σ=“small”. Further, the illumination optical system IL2 of the second embodiment realizes each illumination condition with four emitting ends. However, the number of light emitting surfaces required to realize each illumination condition is not limited to any number and may be only one.

In the illumination optical systems IL1, IL2 of the first, second embodiment, the semiconductor laser unit 2, 8 is moved based on the control of the controller CONT2 to switch the illumination condition. However, such configuration is not exclusive. Specifically, for example, the semiconductor laser unit 2, 8 may be moved manually to switch the illumination condition.

In FIG. 4, FIG. 12, the rectangular outline OL1, OL2 of which center is the optical axis Ax is the rectangular outline obtained by projecting the rectangular outline of the emitting surface 5ae of the lens element 5a of the fly-eye lens 5 by the relay lens 4 and the fly-eye lens 5. The light emitted from the collector lens 3, 9 at a position outside of the outline OL1, OL2 will be emitted from a lens element 5a different from (e.g., adjacent to) the lens element 5a from which the light emitted from the collector lens 3, 9 at a position inside of the outline OL1, OL2 is emitted, with great bending and will not reach the illumination area ILA. Thus, each emitting end in the light emitting area EA1. EA2 and the collector lens 3, 9 may be arranged such that the light emitted from the collector lens 3, 9 is located at the position inside the outline OL1, OL2.

Each of the arrangement of the set of the plurality of emitting ends 1Le, the arrangement of the set of the plurality of emitting ends 1Me, and the arrangement of the set of the plurality of emitting ends 1Se in the light emitting area EA1 may be as follows. That is, in a case where two of the sets are arranged side by side in the Y direction or the X direction in a state that the short sides of the outlines OL1 of the two sets or the long sides of the outlines OL1 of the two sets are overlapped with each other, the emitting ends included in the two sets are arranged, as a whole, in point symmetry with the center of the overlapped short sides or the center of the overlapped long sides as a point of symmetry, and/or in line symmetry with the overlapped short sides or the overlapped long sides as a reference line. Based on such an arrangement, the illuminance distribution in the illumination area ILA can be made more uniform. The same is true regarding each of the arrangement of the set of the plurality of emitting ends 7Ne, the arrangement of the set of the plurality of emitting ends 7Ae, and the arrangement of the set of the plurality of emitting ends 7Pe in the light emitting area EA2.

The illumination optical system IL1, IL2 of the first, second embodiment may include alignment LED configured to emit alignment light in the light emitting area EA1, EA2. The alignment light can be used for alignment between the mask M and the substrate P in the exposure apparatus EX. This configuration can provide alignment light with a small light intensity suitable for alignment. Further, any light source configured to emit light for any desired purpose, different from the light for exposure with which the illumination area ILA is irradiated, can be disposed in the light emitting area EA1, EA2.

In the illumination optical systems IL1, IL2 of the first, second embodiment, the lenses such as the collector lens 3, the relay lens 4 and the condenser lens 6 are not limited to a single lens, but may be a lens group or a lens system including a plurality of lenses. Those lenses are not limited to refractive optical elements such as lenses, but may also be diffractive optical elements that diffract light or reflective optical elements that reflect light. In this description and the appended claims, the terms “collector lens,” “relay lens”, “condenser lens”, and “optical element” refer to above described optical elements in various aspects or combination of those aspects. The relay lens 4 may be omitted as appropriate.

In the illumination optical system IL1, IL2 of the first, second embodiment, the fly-eye lens 5 has a configuration in which a plurality of lens elements 5a is arranged in parallel. However, the fly-eye lens 5 may have a configuration in which the plurality of lens elements 5a is provided integrally.

In the illumination optical system IL1, IL2 of the first, second embodiment, an aperture stop or a variable aperture stop may be disposed at the position of the illumination pupil PP. The variable aperture stop may be used in a manner in which light loss is minimized, in order to assist the switching of the illumination condition performed by switching the light emitting surface.

The illumination optical system IL1, IL2 of the first, second embodiment may be used as the illumination optical system of an exposure apparatus including single projection optical system only, rather than as the illumination optical system of the exposure apparatus EX of a so-called multi-lens system including a plurality of projection optical systems PL. The illumination optical system IL1, IL2 of the first, second embodiment may be used as the illumination optical system of the exposure apparatus of a step-and-repeat system (so-called stepper).

The exposure apparatus EX of the first and second embodiments will be manufactured by assembling various subsystems, including each of the components listed in the appended claims, to maintain a predetermined mechanical, electrical, and optical accuracies. In order to ensure these various accuracies, before and after the assembly, adjustment for achieving optical accuracy of the various optical systems, adjustment for achieving mechanical accuracy of the various mechanical systems, and adjustment for achieving electrical accuracy of the various electrical systems are performed. The assembly process of assembling various subsystems to the exposure apparatus EX includes mechanical connection of various subsystems to each other, wiring connection of electrical circuits, and piping connection of pneumatic circuits. It goes without saying that there is an assembly process of each individual subsystem before the assembly process of assembling the various subsystems to the exposure system EX. After the assembly process of assembling the various subsystems into the exposure apparatus EX is completed, comprehensive adjustment is performed to ensure the various accuracies of the exposure apparatus EX as a whole. The manufacturing of the exposure system EX may be performed in a clean room where the temperature, cleanliness, etc. are controlled.

The device manufacturing method using the illumination optical system IL1, IL2 of the first, second embodiment and the exposure apparatus EX will be described.

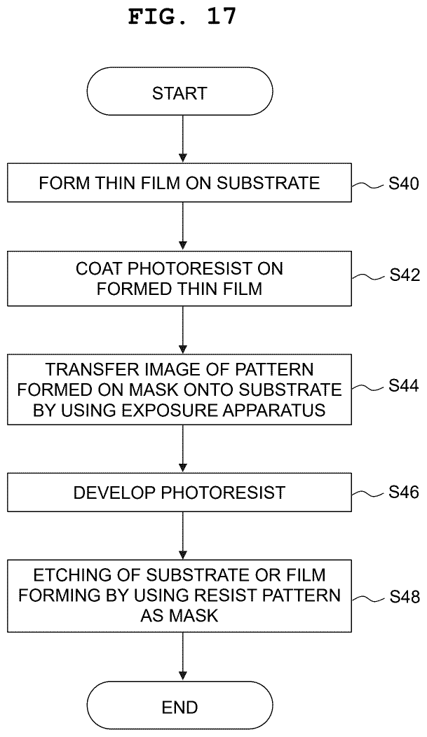

As depicted in FIG. 17, the device manufacturing method for manufacturing semiconductor devices and/or liquid crystal display elements includes a film forming step S40 of forming a thin film having predetermined properties on a substrate P to be a substrate of the semiconductor device, a coating step S42 of coating a photoresist (resist) being a photosensitive material on the formed thin film, an exposure step S44 of exposing (transferring) the pattern MP formed on the mask M onto the substrate P on which the photoresist is coated by using the exposure apparatus EX, and the developing step S46 of developing the substrate P of which the exposure (transfer) has been completed, that is, developing of the photoresist on which the pattern MP has been transferred.

The device manufacturing method further includes a processing step S48 of processing the surface of the substrate P using the resist pattern generated on the surface of the substrate P in the developing step S46 as a mask. Here, the resist pattern refers to a photoresist layer in which concavities and convexities in the shape corresponding to the pattern transferred by the exposure apparatus EX are generated, and the concavities penetrate the photoresist layer. In the processing step S48, the surface of the substrate P is processed via the resist pattern. The processing includes, for example, etching of the surface of the substrate P, and/or forming of a film of a metal, semiconductor material, and/or dielectric etc. on the surface of the substrate P. This process will be repeated a plurality of times.

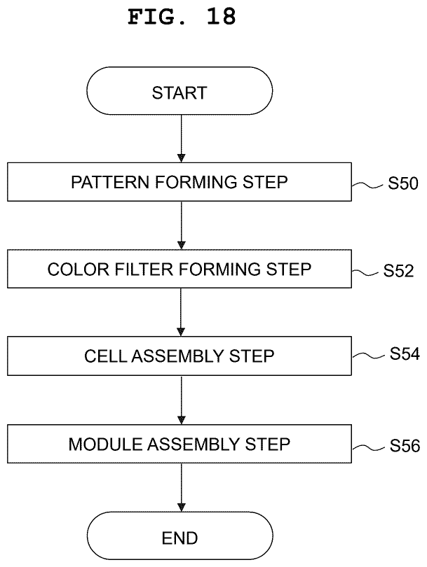

As depicted in FIG. 18, the manufacturing process of a liquid crystal device such as a liquid crystal display element includes a pattern forming step S50, a color filter forming step S52, a cell assembly step S54, and a module assembly step S56. In the pattern forming step S50, a predetermined pattern such as a circuit pattern, an electrode pattern, etc. is formed on a glass substrate coated with the photoresist by using the exposure apparatus EX of the above embodiments. The pattern forming step S50 includes an exposure step similar to the above exposure step S44, i.e., the step of exposing (transferring) a predetermined pattern such as a circuit pattern formed on a mask onto a glass substrate by using the exposure apparatus EX, and a developing step and a processing steps respectively similar to the developing step S46 and the processing step S48 described above.

In the color filter forming step S52, a number of sets each including three dots corresponding to R (Red), G (Green), and B (Blue) will be arranged in a matrix. Alternatively, a color filter in which a plurality of sets each including filters of three stripes of R, G, and B is arranged in the horizontal scanning direction, will be formed. In the cell assembly step S54, a liquid crystal panel (liquid crystal cell) will be assembled using a glass substrate on which a predetermined pattern has been formed in the pattern forming step S50 and a color filter formed in the color filter forming step S52. Specifically, for example, the liquid crystal panel will be formed by injecting liquid crystal between the glass substrate and the color filter. In the module assembly step S56, various components such as electric circuits and a back light for display operation are attached to the liquid crystal panel assembled in the cell assembly step S54.

The illumination optical system IL1, IL2 of the first, second embodiment is not limited to application to exposure apparatuses for manufacturing semiconductor devices, but may also be widely applied to, for example, exposure apparatuses for liquid crystal display elements formed on a square glass plates and/or sheet-like flexible bodies, or display devices such as electroluminescent etc.; exposure apparatuses for manufacturing various devices such as imaging devices (CCDs, etc.), micro machines, thin-film magnetic heads, and DNA chips, etc. Furthermore, the illumination optical system IL1, IL2 of the first, second embodiment can also be applied to exposure processes (exposure apparatus) in manufacturing masks (photomasks, reticles, etc.) with mask patterns for various devices by using photolithography processes.

According to an illumination optical system of an aspect of the present disclosure, exposure in manufacturing of various devices can be performed suitably, by switching illumination condition while reducing loss of light intensity.

What is claimed is:

1. An illumination optical system configured to illuminate an irradiation objective surface, the illumination optical system comprising:
a light source;
a fly-eye lens arranged in an optical path between the light source and the irradiation objective surface; and
a condenser lens configured to overlap a plurality of light fluxes from the fly-eye lens with each other on the irradiation objective surface, wherein:
the light source includes:
a first light emitter which has a first light emitting surface and a first optical element, and which is configured to emit a first light flux emitted from the first light emitting surface via the first optical element; and
a second light emitter which has a second light emitting surface and a second optical element, and which is configured to emit a second light flux emitted from the second light emitting surface via the second optical element;
the light source is configured to selectively emit the first light flux from the first light emitter or the second light flux from the second light emitter; and
the second light emitter is configured such that a shape of a cross section of the second light flux at an incidence surface of the fly-eye lens is different from a shape of a cross section of the first light flux at the incidence surface of the fly-eye lens, or such that a dimension of the cross section of the second light flux at the incidence surface of the fly-eye lens is different from a dimension of the cross section of the first light flux at the incidence surface of the fly-eye lens.

2. The illumination optical system according to claim 1, wherein the second light emitter is configured such that the shape of the cross section of the second light flux at the incidence surface of the fly-eye lens is different from the shape of the cross section of the first light flux at the incidence surface of the fly-eye lens.

3. The illumination optical system according to claim 2, wherein a shape of the second light emitting surface is different from a shape of the first light emitting surface.

4. The illumination optical system according to claim 2, wherein the second light emitter includes an axicon lens arranged in an optical path between the second light emitting surface and the second optical element.

5. The illumination optical system according to claim 1, wherein the second light emitter is configured such that the shape of the cross section of the second light flux at the incidence surface of the fly-eye lens is the same as the shape of the cross section of the first light flux at the incidence surface of the fly-eye lens, and that the dimension of the cross section of the second light flux at the incidence surface of the fly-eye lens is different from the dimension of the cross section of the first light flux at the incidence surface of the fly-eye lens.

6. The illumination optical system according to claim 5, wherein a shape of the second light emitting surface and a shape of the first light emitting surface are the same as each other, and a dimension of the second light emitting surface and a dimension of the first light emitting surface are different from each other.

7. The illumination optical system according to claim 5, wherein:
the first optical element is a condenser optical element having a first focal length, a front focal point of the first optical element being located on the first light emitting surface; and
the second optical element is a condenser optical element having a second focal length different from the first focal length, a front focal point of the second optical element being located on the second light emitting surface.

8. The illumination optical system according to claim 1, wherein the first light emitter includes a plurality of first sub light emitters, the plurality of first sub light emitters each including the first light emitting surface and the first optical element and each being configured to emit the first light flux,
the illumination optical system further comprising a relay lens configured to overlap a plurality of the first fluxes from the plurality of first sub light emitters with each other on the incidence surface of the fly-eye lens.

9. The illumination optical system according to claim 8, wherein:
the second light emitter includes a plurality of second sub light emitters, the plurality of second sub light emitters each including the second light emitting surface and the second optical element and each being configured to emit the second light flux; and
the relay lens is configured to overlap a plurality of the second fluxes from the plurality of second sub emitters with each other on the incidence surface of the fly-eye lens.

10. The illumination optical system according to claim 8, wherein:
the light source includes an illuminance distribution controller configured to change illuminance distribution in the irradiation objective surface; and
the illuminance distribution controller is configured to change the illuminance distribution in the irradiation objective surface by changing a light intensity of the first light flux to be emitted from at least one of the plurality of first sub light emitters and/or by switching a light emitter to emit the first light flux among the plurality of first sub light emitters.

11. The illumination optical system according to claim 8, wherein in a plane orthogonal to an optical axis of the illumination optical system, the plurality of first sub light emitters is arranged in point symmetry with a position of the optical axis as a point of symmetry and/or in line symmetry with a straight line extending through the position of the optical axis in the plane orthogonal to the optical axis as a reference line.

12. The illumination optical system according to claim 8, wherein:
the plurality of first sub light emitters of the first light emitter is arranged in a plane orthogonal to an optical axis of the illumination optical system,
the plurality of first sub light emitters is arranged such that, regarding a certain light flux being each of the plurality of the first light fluxes to be emitted from the plurality of first sub light emitters and to enter the incidence surface of the fly-eye lens:
an opposing light flux opposing the certain light flux exists, an optical axis of the illumination optical system and/or a straight line extending through a position of the optical axis in a plane orthogonal to the optical axis being interposed between the opposing light flux and the certain light flux; and
an incidence angle of the certain light flux to the incidence surface of the fly-eye lens and an incidence angle of the opposing light flux to the incidence surface of the fly-eye lens are the same as each other.

13. The illumination optical system according to claim 1, wherein:
the light source includes:
a source; and
a first light guide and a second light guide each configured to transmit light emitted from the source;
the first light emitting surface is an emitting end of the first light guide; and
the second light emitting surface is an emitting end of the second light guide.

14. The illumination optical system according to claim 13 further comprising a mover configured to move the source between a first position at which the source emits light to an incidence end of the first light guide and a second position at which the source emits light to an incidence end of the second light guide.

15. The illumination optical system according to claim 1, wherein:
the light source includes a first solid state light source and a second solid state light source;
the first light emitting surface is an light emitting surface of the first solid state light source; and
the second light emitting surface is an light emitting surface of the second solid state light source.

16. An exposure apparatus comprising:
the illumination optical system as defined in claim 1 configured to illuminate the irradiation objective surface; and
a projection optical system configured to irradiate a substrate with a light from the irradiation objective surface.

17. An exposure apparatus configured to perform a scanning exposure of a pattern on a mask onto a substrate, the exposure apparatus comprising:
a plurality of illumination optical systems configured to illuminate the pattern;
a plurality of projection optical system configured to form an image of the pattern on the substrate; and
a controller configured to control the scanning exposure, wherein:
the plurality of illumination optical system includes:
a first illumination optical system configured to irradiate a first illumination area with illumination light; and
a second illumination optical system configured to irradiate a second illumination area with illumination light, the second illumination optical system being the illumination optical system as defined in claim 8;
the first illumination area and the second illumination area overlap with each other in a non-scanning direction orthogonal to a scanning direction in which the exposure apparatus performs the scanning exposure; and
the controller is configured to change illuminance distribution of the second illumination optical system based on illuminance distribution of the first illumination optical system.

18. A device manufacturing method comprising:
exposing a pattern onto the substrate by using the exposure apparatus as defined in claim 16;
forming a mask layer on a surface of the substrate by developing the substrate to which the pattern has been exposed, the mask layer having a shape corresponding to the pattern; and
processing the surface of the substrate via the mask layer.
